(19) United States
(12) Patent Application Publication
(10) Pub. No.: US 2022/0246540 A1
(43) Pub. Date: Aug. 4, 2022

(54) PACKAGING STRUCTURE AND FORMATION METHOD THEREOF

(71) Applicants: NANTONG TONGFU MICROELECTRONICS CO., LTD, Nantong (CN); TONGFU MICROELECTRONICS CO., LTD, Nantong (CN)

(72) Inventors: Lei SHI, Nantong (CN); Yujuan TAO, Nantong (CN)

(21) Appl. No.: 17/629,692

(22) PCT Filed: Jul. 17, 2020
(86) PCT No.: PCT/CN2020/102764

§ 371 Date: Jan. 24, 2022

(30) Foreign Application Priority Data
Jul. 26, 2019 (CN) 201910681475.4
Jul. 26, 2019 (CN) 201910681477.3
Jul. 26, 2019 (CN) 201910681481.X
Jul. 26, 2019 (CN) 201910681487.7
Jul. 26, 2019 (CN) 201910681794.5
Jul. 26, 2019 (CN) 201910681796.4

(51) Int. Cl. H01L 23/552; H01L 21/56; H01L 23/00

(52) U.S. Cl. CPC H01L 23/552; H01L 21/561; H01L 21/568; H01L 24/20; H01L 24/96; H01L 24/97; H01L 2224/13024; H01L 2224/2101; H01L 2224/214; H01L 2224/95001; H01L 2224/211; H01L 24/13; H01L 2224/13026; H01L 2924/3025

(57) ABSTRACT

Packaging structure and formation method are provided. The packaging structure includes a pre-encapsulation panel, which includes an encapsulation layer containing a plurality of semiconductor chips. Each semiconductor chip includes a functional surface and a non-functional surface opposite to the functional surface. A plurality of pads are formed on the functional surface, and the encapsulation layer exposes the plurality of pads. The packaging structure also includes a first shielding layer and a second shielding layer disposed between a semiconductor chip and the encapsulation layer. The first shielding layer covers the non-functional surface and a sidewall surface of the semiconductor chip. The second shielding layer is disposed between the first shielding layer and the encapsulation layer and fully covers a surface of the first shielding layer. Further, the packaging structure includes an external contact structure disposed on a back side of the pre-encapsulation panel and connected to a pad.

### CROSS-REFERENCES TO RELATED APPLICATIONS

This application claims the priority of Chinese patent applications No. 201910681487.7, filed on Jul. 26, 2019; No. 201910681794.5, filed on Jul. 26, 2019; No. 201910681796.4, filed on Jul. 26, 2019; No. 201910681481.X, filed on Jul. 26, 2019; No. 201910681477.3, filed on Jul. 26, 2019; and No. 201910681475.4, filed on Jul. 26, 2019, the entirety of all of which is incorporated herein by reference.

### FIELD OF THE DISCLOSURE

The present disclosure generally relates to the field of semiconductor manufacturing and, more particularly, relates to a packaging structure and formation method thereof.

### BACKGROUND

The rapid development of new-generation electronic products has now moved toward integrated circuit packaging for high density, high frequency, miniaturization, and high integration. However, strong electromagnetic waves may often be generated from high-frequency chips, which causes undesirable interference or noise on the chip inside the packaging structure. In addition, the density of electronic components increases, and the distance between transmission wires is getting closer, which causes the electromagnetic interference issues from the inside and outside of the integrated circuit packaging structure to get worse, and reduces the quality and service life of the integrated circuit.

In electronic devices and electronic products, electromagnetic interference (EMI) energy is transmitted through conductive coupling and radiative coupling. To meet the requirements of electromagnetic compatibility, filter technology is needed to suppress the conductive coupling. In other words, an EMI filter device may be used to suppress the conductive coupling. Shielding technology is needed to suppress the radiative coupling. In the current case that the electromagnetic spectrum has become increasingly dense, the electromagnetic power density in a unit volume has dramatically increased, and a large number of high-level and low-level devices or equipment have been mixed in use, which causes the electromagnetic environment of devices and systems to be deteriorating, the importance of electromagnetic shielding becomes more prominent.

An existing electromagnetic shielding solution includes providing a magnetic field shielding layer on the semiconductor packaging structure, to shield the electromagnetic interference between chips. However, the effect of the existing electromagnetic shielding still needs to be improved. The disclosed packaging structure and formation method are directed to solve one or more problems set forth above and other problems in the art.

### BRIEF SUMMARY OF THE DISCLOSURE

One aspect of the present disclosure includes a packaging structure. The packaging structure includes a pre-encapsulation panel. The pre-encapsulation panel includes an encapsulation layer, and the encapsulation layer contains a plurality of semiconductor chips. Each semiconductor chip of the plurality of semiconductor chips includes a functional surface and a non-functional surface opposite to the functional surface. A plurality of pads are formed on the functional surface, and the encapsulation layer exposes the plurality of pads on the functional surface. The packaging structure also includes a first shielding layer and a second shielding layer disposed between a semiconductor chip of the plurality of semiconductor chips and the encapsulation layer. The first shielding layer covers the non-functional surface and a sidewall surface of the semiconductor chip. The second shielding layer is disposed between the first shielding layer and the encapsulation layer and fully covers a surface of the first shielding layer on the non-functional surface and the sidewall surface of the semiconductor chip. Further, the packaging structure includes an external contact structure disposed on a back side of the pre-encapsulation panel and connected to a pad of the plurality of pads.

Another aspect of the present disclosure includes a packaging structure. The packaging structure includes a pre-encapsulation panel. The pre-encapsulation panel includes an encapsulation layer, and the encapsulation layer contains a plurality of semiconductor chips. Each semiconductor chip of the plurality of semiconductor chips includes a functional surface and a non-functional surface opposite to the functional surface. A plurality of pads are formed on the functional surface, and the encapsulation layer exposes the plurality of pads on the functional surface. The packaging structure also includes a bottom shielding layer formed on the functional surface of a semiconductor chip of the plurality of semiconductor chips. The bottom shielding layer covers the entire functional surface of the semiconductor chip, and peripheral edge of the bottom shielding layer is flush with a surrounding sidewall of the semiconductor chip. The plurality of pads penetrate through the bottom shielding layer, and a pad of the plurality of pads is isolated from the bottom shielding layer by an isolation layer. In addition, the packaging structure includes a first shielding layer disposed between the semiconductor chip and the encapsulation layer. The first shielding layer covers the non-functional surface and a sidewall surface of the semiconductor chip, and the first shielding layer is connected to the peripheral edge of the bottom shielding layer. Further, the packaging structure includes an external contact structure disposed on a back side of the pre-encapsulation panel and connected to the pad.

Another aspect of the present disclosure includes a method for forming a packaging structure. The method includes providing a plurality of semiconductor chips. Each semiconductor chip of the plurality of semiconductor chips includes a functional surface and a non-functional surface opposite to the functional surface, and a plurality of pads are formed on the functional surface. The method also includes providing a carrier board, and adhering the functional surface of the each semiconductor chip to the carrier board. In addition, the method includes forming a first shielding layer to cover the non-functional surface and a sidewall surface of a semiconductor chip of the plurality of semiconductor chips. Moreover, the method includes forming one or more of a second shielding layer and a bottom shielding layer. The second shielding layer fully covers a surface of the first shielding layer. The bottom shielding layer covers the entire functional surface of the semiconductor chip, and peripheral edge of the bottom shielding layer is flush with a surrounding sidewall of the semiconductor chip. The plurality of pads penetrate through the bottom shielding layer, and a pad of the plurality of pads is isolated from the bottom shielding layer by an isolation layer. Further, the method includes forming an encapsulation layer over the first shielding layer and over the carrier board between semiconductor chips of the plurality of semiconductor chips, and forming a pre-encapsulation panel by peeling off the carrier board. Furthermore, the method includes forming an external contact structure on the back side of the pre-encapsulation panel and connected to the pad.

The present disclosure has the following beneficial effects. In the disclosed embodiments of the present disclosure, the packaging structure may include the first shielding layer and the second shielding layer disposed between the semiconductor chip and the encapsulation layer. The first shielding layer may cover the non-functional surface and the sidewall surface of the semiconductor chip, and the surface of the first shielding layer may have an ellipsoidal shape. The second shielding layer may be located between the first shielding layer and the encapsulation layer, and may fully cover the surface of the first shielding layer on the non-functional surface and the sidewall surface of the semiconductor chip.

The first shielding layer having an ellipsoidal shape may uniformly and fully cover the non-functional surface and the sidewall surface of the semiconductor chip. Further, when forming the second shielding layer on the ellipsoidal surface of the first shielding layer, the second shielding layer may not have the issues of uneven thickness and poor edge coverage. Therefore, the overall shielding layer formed by both the first shielding layer and the second shielding layer may be intact, which may improve the shielding effect.

In addition, the first shielding layer may be a magnetic field shielding layer, and the formed second shielding layer may be an electric field shielding layer. Alternatively, the first shielding layer may be an electric field shielding layer, and the formed second shielding layer may be a magnetic field shielding layer. The formed first shielding layer and the second shielding layer having the above disclosed structure may shield the electric field and the magnetic field, respectively, thereby improving the shielding effect of the shielding layer. Further, the second shielding layer may cover the first shielding layer where the thickness is uneven and edge is not well covered. Therefore, the overall shielding layer formed by both the first shielding layer and the second shielding layer may be intact, which may improve the shielding effect.

Moreover, the intermediate material layer may be formed on the non-functional surface and sidewall surface of the semiconductor chip. The intermediate material layer may have an ellipsoidal surface. The first shielding layer may be formed on the surface of the intermediate material layer, and the first shielding layer may also have an ellipsoidal surface. By forming the intermediate material layer having an ellipsoidal surface, the first shielding layer made of different materials may be formed on the intermediate material layer through various processes, and the formed first shielding layer may also have an ellipsoidal surface. When forming the first shielding layer on the ellipsoidal surface of the intermediate material layer, the first shielding layer may not be affected by the sharp corner or steep sidewall, such that the formed first shielding layer may not have the issues of uneven thickness and poor edge coverage, thereby improving the integrity of the shielding layer.

Further, after forming the external contact structure, the pre-encapsulation panel may be cut to form a plurality of discrete packaging structures. Therefore, the mass production of the packaging structures having the first shielding layer and the second shielding layer may be achieved, thereby improving the production efficiency.

Further, the bottom shielding layer may be formed on the functional surface of the semiconductor chip. The bottom shielding layer may cover the entire functional surface of the semiconductor chip. The peripheral edge of the bottom shielding layer may be flush with the peripheral sidewall of the semiconductor chip. The plurality of pads may penetrate through the bottom shielding layer, and the pad may be isolated from the bottom shielding layer through the isolation layer. When forming the first shielding layer, the first shielding layer may be connected to the peripheral edge of the bottom shielding layer.

Further, the process of forming the bottom shielding layer may be integrated with the existing semiconductor chip manufacturing process. The bottom shielding layer and the pad may be simultaneously formed, which may simplify the manufacturing process, may reduce the process difficulty, and may improve the efficiency.

In the present disclosure, after forming the first shielding layer, the second shielding layer may also be formed on the first shielding layer, such that the second shielding layer may cover the first shielding layer where the thickness is uneven and edge is not well covered. Therefore, the overall shielding layer formed by both the first shielding layer and the second shielding layer may be intact, which may improve the shielding effect. Because the bottom shielding layer is also formed on the functional surface of the semiconductor chip, when forming the first shielding layer, the first shielding layer may be connected to the peripheral edge of the bottom shielding layer. Therefore, the semiconductor chip in the packaging structure may be fully or comprehensively covered by the bottom shielding layer and the first shielding layer. The electric field and magnetic field may not enter the packaging structure through the bottom of the packaging structure to bring electromagnetic interference to the semiconductor chip, thereby achieving the all-round electromagnetic shielding for the semiconductor chip, and further improving the electromagnetic shielding effect.

Other aspects of the present disclosure can be understood by those skilled in the art in light of the description, the claims, and the drawings of the present disclosure.

### BRIEF DESCRIPTION OF THE DRAWINGS

To more clearly illustrate the embodiments of the present disclosure, the drawings will be briefly described below. The drawings in the following description are certain embodiments of the present disclosure, and other drawings may be obtained by a person of ordinary skill in the art in view of the drawings provided without creative efforts.

FIGS. 1-13 illustrate schematic diagrams of semiconductor structures corresponding to certain stages of an exemplary method for forming a packaging structure consistent with various disclosed embodiments of the present disclosure;

FIGS. 14-20 illustrate schematic diagrams of semiconductor structures corresponding to certain stages of another exemplary method for forming a packaging structure consistent with various disclosed embodiments of the present disclosure;

FIGS. 21-33 illustrate schematic diagrams of semiconductor structures corresponding to certain stages of another exemplary method for forming a packaging structure consistent with various disclosed embodiments of the present disclosure;

FIGS. 34-40 illustrate schematic diagrams of semiconductor structures corresponding to certain stages of another exemplary method for forming a packaging structure consistent with various disclosed embodiments of the present disclosure; and

FIGS. 41-58 illustrate schematic diagrams of semiconductor structures corresponding to certain stages of another exemplary method for forming a packaging structure consistent with various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or the alike parts. The described embodiments are some but not all of the embodiments of the present disclosure. Based on the disclosed embodiments, persons of ordinary skill in the art may derive other embodiments consistent with the present disclosure, all of which are within the scope of the present disclosure.

A magnetic field shielding layer for shielding a semiconductor packaging structure is often formed by a sputtering process. Because the semiconductor packaging structure often has a substantially thick thickness, and a rectangular shape, the semiconductor packaging structure has a plurality of vertexes and a substantially steep sidewall. When forming the magnetic field shielding layer to cover the semiconductor packaging structure by a sputtering process, the thickness of the formed magnetic field shielding layer is likely to be uneven, and an edge of the semiconductor packaging structure may not be covered.

Further, the magnetic field shielding layer is only formed on the non-functional surface and the sidewall surface of the semiconductor chip or packaging structure, the surface where the pad is located is still exposed to the environment. Thus, the magnetic field shielding layer is incomplete, and the magnetic field shielding layer contains a large gap. Therefore, the shielding effect of the magnetic field shielding layer is difficult to be ensured.

The present disclosure provides a packaging structure and a method for forming the packaging structure. To clearly illustrate the above objects, features and advantages of the present disclosure, the specific embodiments of the present disclosure may be described in detail with reference to the accompanying drawings. For illustrative purposes, the schematic diagram may be partially enlarged not according to a general scale, and the schematic diagram is merely an example, which may not tend to limit the protection scope of the present disclosure. In addition, the actual production may include the three-dimensional dimensions of length, width and depth.

### Exemplary Embodiment 1

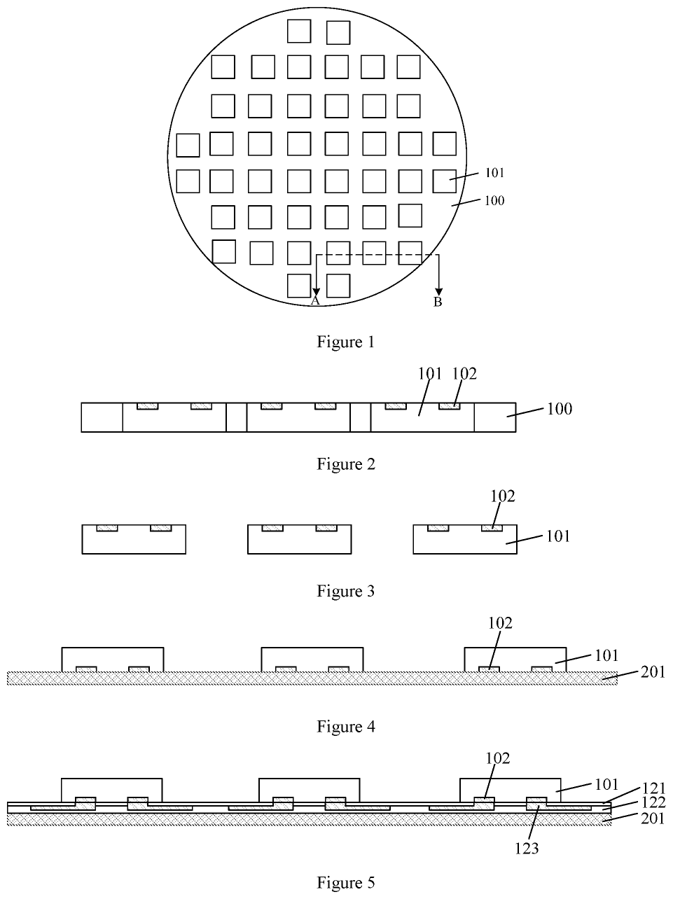

FIGS. 1-13 illustrate schematic diagrams of semiconductor structures corresponding to certain stages of a method for forming a packaging structure consistent with various disclosed embodiments of the present disclosure. FIG. 2 illustrates a schematic AB sectional view of a semiconductor structure in FIG. 1. Referring to FIGS. 1-3, a plurality of semiconductor chips 101 may be provided. Each semiconductor chip 101 may include a functional surface and a non-functional surface opposite to the functional surface. A plurality of pads 102 may be disposed on the functional surface.

An integrated circuit (not illustrated in the Figure) may be formed in/on the functional surface of the semiconductor chip 101. The plurality of pads 102 on the functional surface of the semiconductor chip 101 may be electrically connected to the integrated circuit in the semiconductor chip 101. A pad 102 may serve as a port for the integrated circuit in the semiconductor chip 101 to be electrically connected to an external circuit.

The functional surface of the semiconductor chip 101 may be a surface for forming the integrated circuit, and the non-functional surface may be a surface opposite to the functional surface. The surrounding surface between the functional surface and the non-functional surface may be the sidewall of the semiconductor chip 101.

The semiconductor chip 101 may be formed by a semiconductor integrated manufacturing process. Referring to FIG. 1 and FIG. 2, a wafer 100 may be provided. The wafer 100 may include a plurality of chip regions arranged in rows and columns and a scribe-line region between the chip regions. The plurality of chip regions of the wafer 100 may be used for correspondingly forming the plurality of semiconductor chips 101. The plurality of pads 102 may be formed on the functional surface of the semiconductor chip 101. Referring to FIG. 3, after forming the plurality of pads, the wafer 100 may be cut along the scribe-line to form the plurality of discrete semiconductor chips 101.

In one embodiment, the wafer 100 may be monocrystalline silicon (Si), monocrystalline germanium (Ge), silicon germanium (GeSi), or silicon carbide (SiC). In another embodiment, the wafer may be silicon on insulator (SOI), or germanium on insulator (GOI). In certain embodiments, the wafer may be any other suitable material, e.g., Group III-V compounds, such as allium arsenide (GaAs), etc.

In one embodiment, the integrated circuit in the semiconductor chip 101 may include a plurality of semiconductor devices (e.g., transistor, memory, diode and/or triode, etc.) and an interconnection structure (including metal wire and metal plug) for connecting the semiconductor devices. In one embodiment, the semiconductor chip 101 may be a semiconductor chip that requires electromagnetic shielding.

Referring to FIG. 4, a carrier board 201 may be provided. The functional surface of each semiconductor chip 101 may be adhered to the carrier board 201. The carrier board 201 may provide a supporting platform for subsequent processes. In one embodiment, the carrier board 201 may be a glass carrier board, a silicon carrier board, or a metal carrier board. In another embodiment, the carrier board 201 may be a carrier board made of any other suitable material.

The semiconductor chip 101 may be adhered to the surface of the carrier board 201 by an adhesive layer. The functional surface (or the pad 102) of the semiconductor chip 101 may face toward an adhesive surface of the carrier board 201. The plurality of semiconductor chips 101 may be uniformly adhered to the carrier board 201 in rows and columns.

The adhesive layer may be made of various materials. In one embodiment, the adhesive layer may be made of an UV glue. The UV glue may be a kind of glue material that can be reacted under irradiation of ultraviolet light of special wavelength. The UV glue may be divided into two types according to the change in viscosity after irradiation of ultraviolet light. One kind of the UV glue may be an UV curing glue, that is, the photoinitiator or photosensitizer in the material may absorb ultraviolet light under radiation of ultraviolet light to produce active radicals or cations, which may initiate monomer polymerization, cross-linking and graft chemical reactions to enable the UV curing glue to change from liquid to solid within a few seconds, thereby bonding the surfaces of objects being in contact. Another kind of the UV glue may have substantially high viscosity when not exposed to UV light, and after being exposed to ultraviolet light, the cross-linking chemical bonds in the UV glue may be broken, which may cause the viscosity to significantly decrease or even disappear. The UV glue used for the adhesive layer here may be the latter one. The adhesive layer may be formed by a film-sticking process, a glue-printing process, or a glue-rolling process.

In certain embodiments, the adhesive layer may be made of epoxy glue, polyimide glue, polyethylene glue, benzocyclobutene glue, or polybenzoxazole glue.

In one embodiment, referring to FIG. 5, before adhering the semiconductor chip 101 on the carrier board 201, an insulating layer and a rewiring layer 123 located in the insulating layer may be formed over the carrier board 201. The insulating layer may include a first insulating layer 121 and a second insulating layer 122, and the first insulating layer 121 may be disposed over the second insulating layer 122. The insulating layer (first insulating layer) may expose a partial surface of the rewiring layer 123. The functional surface of each semiconductor chip 101 may be adhered to the rewiring layer 123 over the carrier board 201. In one embodiment, the pad 102 may be adhered to the rewiring layer 123 through a solder layer.

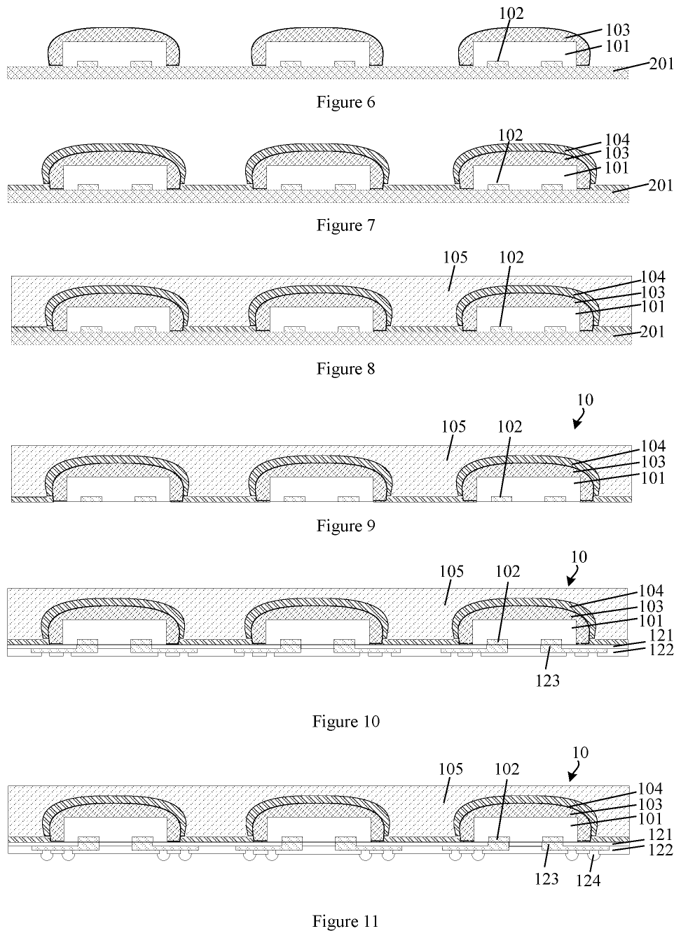

Referring to FIG. 6, a first shielding layer 103 may be formed to cover the non-functional surface and the sidewall surface of the semiconductor chip 101. The surface of the first shielding layer 103 may have an ellipsoidal shape.

In one embodiment, the first shielding layer 103 may be directly formed on the non-functional surface and the sidewall surface of each semiconductor chip 103 through a dispensing process or a screen-printing process. The first shielding layer 103 may not be formed on the carrier board on both sides of the semiconductor chip 101. The formed first shielding layer 103 may uniformly and fully cover the non-functional surface and the sidewall surface of the semiconductor chip.

The first shielding layer 103 may be made of solder or conductive silver paste. The solder or conductive silver paste may be dispensed on the non-functional surface and the sidewall surface of the semiconductor chip 101 through the dispensing process to form the first shielding layer 103 having an ellipsoidal surface. A solder layer may be formed on the non-functional surface and the sidewall surface of the semiconductor chip 101 through the screen-printing process, and a reflow process may be performed to form the first shielding layer 103 having an ellipsoidal surface. The solder may include one or more of tin, tin silver, tin lead, tin silver copper, tin silver zinc, tin zinc, tin bismuth indium, tin indium, tin gold, tin copper, tin zinc indium and tin silver antimony.

The surface of the first shielding layer 103 having an ellipsoidal shape may refer to that the surface of the first shielding layer 103 may not have a sharp corner, and the surface of the first shielding layer 103 may have an arc-shape. The formed first shielding layer 103 having an ellipsoidal surface may uniformly and fully cover the non-functional surface and the sidewall surface of the semiconductor chip 101. Further, when subsequently forming a second shielding layer on the ellipsoidal surface of the first shielding layer 103, the second shielding layer may not have the issues of uneven thickness and poor edge coverage. Therefore, the overall shielding layer formed by both the first shielding layer 103 and the subsequently formed second shielding layer may be intact, which may improve the shielding effect.

In certain embodiments, an intermediate material layer (not illustrated in the Figure) may be formed on the non-functional surface and sidewall surface of the semiconductor chip 101. The intermediate material layer may have an ellipsoidal surface. The first shielding layer may be formed on the surface of the intermediate material layer, and the first shielding layer may also have an ellipsoidal surface. By forming the intermediate material layer having an ellipsoidal surface, the first shielding layer made of different materials may be formed on the intermediate material layer through various processes, and the formed first shielding layer may also have an ellipsoidal surface. In addition, when forming the first shielding layer on the ellipsoidal surface of the intermediate material layer, the first shielding layer may not be affected by the sharp corner or steep sidewall, such that the formed first shielding layer may not have the issues of uneven thickness and poor edge coverage, thereby improving the integrity of the shielding layer.

In one embodiment, the material of the intermediate material layer may include non-conductive glue, conductive silver glue, fluid resin, or solder, and the process for forming the intermediate material layer may include a dispensing process or a screen-printing process. The first shielding layer having an ellipsoidal surface may be formed on the intermediate material layer by a sputtering process, a selective electroplating process, a dispensing process, or a screen-printing process. Correspondingly, the material of the first shielding layer may include copper, tungsten, aluminum, solder, or conductive silver paste. In another embodiment, the material of the first shielding layer may include material of subsequently mentioned magnetic field shielding layer and electric field shielding layer.

In one embodiment, the first shielding layer 103 may be a shielding layer for electric and magnetic fields. The first shielding layer 103 may be used for shielding electric and magnetic fields. The subsequently formed second shielding layer may be a shielding layer for electric and magnetic fields. The second shielding layer may be used for shielding electric and magnetic fields.

The existing shielding layer may not only shield electric field but also shield magnetic field. The existing single-layer shielding layer made of a specific material or multi-layer shielding layer made of a same material or similar materials only has a desired shielding effect on the electric field, and has a substantially poor shielding effect on the magnetic field, thereby affecting the shielding effect of the shielding layer. Therefore, in one embodiment, the first shielding layer 103 may be a magnetic field shielding layer, and the first shielding layer may be used for shielding the magnetic field. The subsequently formed second shielding layer may be an electric field shielding layer, and the second shielding layer may be used for shielding the electric field. In another embodiment, the first shielding layer may be an electric field shielding layer, and the first shielding layer may be used for shielding the electric field. The second shielding layer may be a magnetic field shielding layer, and the second shielding layer may be used for shielding the magnetic field.

The formed first shielding layer and the second shielding layer having the above disclosed structure may shield the electric field and the magnetic field, respectively, thereby improving the shielding effect of the shielding layer. When the first shielding layer 103 is an electric field shielding layer, the material of the first shielding layer 103 (electric field shielding layer) may include copper, tungsten, aluminum. When the first shielding layer 103 is a magnetic field shielding layer, the material of the first shielding layer 103 (magnetic field shielding layer) may include CoFeB alloy, CoFeTa alloy, NiFe alloy, Co, CoFe alloy, CoPt alloy or an alloy of Ni, Co and Fe. The first shielding layer 103 may be formed by a sputtering process, a physical vapor deposition process, an atomic layer deposition process, a chemical vapor deposition, or any other suitable process.

Referring to FIG. 7, a second shielding layer 104 may be formed on the first shielding layer 103. In one embodiment, the second shielding layer 104 may be formed by a sputtering process. The material of the second shielding layer 104 may include metal such as copper, tungsten, aluminum, etc. The formed second shielding layer 104 may not only be formed on the surface of the first shielding layer 103 covering the non-functional surface and the sidewall surface of the semiconductor chip, but also be formed on the surface of the carrier board 201 on both sides of the semiconductor chip 101.

In certain embodiments, the second shielding layer may merely be formed on the surface of the first shielding layer 103 covering the non-functional surface and the sidewall surface of the semiconductor chip. The second shielding layer may be formed by a selective electroplating process, a dispensing process, or a screen-printing process. Thus, the formed second shielding layer may substantially well cover the first shielding layer, and the second shielding layer may be prevented to avoid uneven thickness or poor coverage issue, which may further ensure the integrity of the overall shielding layer formed by both the first shielding layer 103 and the second shielding layer. Further, the semiconductor chip may not need to be subsequently removed by additional mask and etching processes.

The material of the second shielding layer may include copper, solder or conductive silver paste. When the material of the second shielding layer is copper, the second shielding layer may be formed by a selective electroplating process. In one embodiment, a mask layer (not illustrated in the Figure) may be first formed on the carrier board 201, and the mask layer may have an opening exposing the first shielding layer 103 on the non-functional surface and the sidewall surface of the semiconductor chip 101. The second shielding layer may be formed in the opening using the first shielding layer 103 as a conductive layer during the electroplating process. The mask layer may be removed.

The material of the second shielding layer may be solder or conductive silver paste, and the second shielding layer may be formed by a dispensing process or a screen-printing process. In one embodiment, when performing the dispensing process, solder or conductive silver paste may be dispensed on the surface of the first shielding layer 103 formed on the sidewall surface and the non-functional surface of the semiconductor chip 101. When performing the screen-printing process, a screen with a mesh may be first disposed on the carrier board 201, and each semiconductor chip 101 may be located in a corresponding mesh in the screen. The solder may be brushed into the mesh, and the solder may cover the surface of the first shielding layer 103 formed on the sidewall surface and the non-functional surface of the semiconductor chip 101. The screen may be removed, and the solder may be reflowed to form the second shielding layer on the first shielding layer 103.

In one embodiment, the solder may include one or more of tin, tin silver, tin lead, tin silver copper, tin silver zinc, tin zinc, tin bismuth indium, tin indium, tin gold, tin copper, tin zinc indium, and tin silver antimony.

In one embodiment, the first shielding layer 103 may be a magnetic field shielding layer, and the formed second shielding layer 104 may be an electric field shielding layer. In another embodiment, the first shielding layer 103 may be an electric field shielding layer, and the formed second shielding layer 104 may be a magnetic field shielding layer. The formed first shielding layer and the second shielding layer having the above disclosed structure may shield the electric field and the magnetic field, respectively, thereby improving the shielding effect of the shielding layer.

When the second shielding layer 104 is an electric field shielding layer, the material of the second shielding layer 104 (electric field shielding layer) may include copper, tungsten, aluminum. When the second shielding layer 104 is a magnetic field shielding layer, the material of the second shielding layer 104 (magnetic field shielding layer) may include CoFeB alloy, CoFeTa alloy, NiFe alloy, Co, CoFe alloy, CoPt alloy or an alloy of Ni, Co and Fe. The second shielding layer 104 may be formed by a sputtering process, a physical vapor deposition process, an atomic layer deposition process, a chemical vapor deposition, or any other suitable process.

Referring to FIG. 8, an encapsulation layer 105 may be formed over the second shielding layer 104 and the carrier board 201 between the semiconductor chips 101. The encapsulation layer 105 may be used to seal and fix the semiconductor chip 101, which may facilitate to subsequently form a pre-encapsulation panel.

The material of the encapsulation layer 105 may include one or more of epoxy resin, polyimide resin, benzocyclobutene resin, polybenzoxazole resin, polybutylene terephthalate, polycarbonate, polyethylene terephthalate, polyethylene, polypropylene, polyolefin, polyurethane, polyolefin, polyethersulfone, polyamide, polyurethane, ethylene-vinyl acetate, and polyvinyl alcohol. The encapsulation layer 105 may be formed by an injection molding process, a transfer molding process, or any other suitable process.

Referring to FIG. 9, the carrier board 201 (referring to FIG. 8) may be peeled off to form a pre-encapsulation panel 10. A back side of the pre-encapsulation panel 10 may expose the functional surface (and pad) of the semiconductor chip 101. The back side of the pre-encapsulation panel 10 may be the surface in contact with the carrier board 201 (referring to FIG. 8).

The adhesive layer may be removed by chemical etching, mechanical peeling, chemical mechanical polishing (CMP), mechanical grinding, thermal baking, etc., such that the carrier board 201 may be peeled off.

Referring to FIG. 10 and FIG. 11, an external contact structure connected to the pad 102 may be formed on the back side of the pre-encapsulation panel 10. In one embodiment, the external contact structure may include a rewiring layer 123 located on the back side of the pre-encapsulation panel 10 and connected to the pad 102, and an external contact element 124 located on the rewiring layer 123 and connected to the rewiring layer 123. The pad 102 on each semiconductor chip 101 may be connected to a corresponding external contact structure.

In one embodiment, the process of forming the rewiring layer 123 and the external contact element 124 may include following. An insulating layer (first insulating layer) 121 may be formed on the back side of the pre-encapsulation panel 10. The insulating layer (first insulating layer) 121 may have an opening that exposes the surface of the pad 102. The material of the insulating layer (first insulating layer) 121 may include silicon nitride, borosilicate glass, phosphorous silicate glass, or borophosphosilicate glass. The rewiring layer 123 may be formed in the opening and on partial surface of the insulating layer (first insulating layer) 121. An external contact element 124 may be formed on the surface of the rewiring layer outside the opening.

In one embodiment, the external contact element 124 may be a solder ball. In another embodiment, the external contact element 124 may include a metal pillar and a solder ball located on the metal pillar. The process of forming the external contact element 124 may include following. An insulating layer (second insulating layer) 122 may be formed on the insulating layer (first insulating layer) 121 and on the rewiring layer 123. The insulating layer (second insulating layer) 122 may have a second opening exposing partial surface of the rewiring layer 123 on the surface of the insulating layer (first insulating layer) 121. The external contact element 124 may be formed in the second opening.

In one embodiment, a conductive contact structure (not illustrated in the Figure) that electrically connects the first shielding layer 103 and a portion of the rewiring layer 123 may be formed on the insulating layer (first insulating layer) 121, such that the shielding layer may discharge or block external electrostatic interference through the portion of the rewiring layer 123.

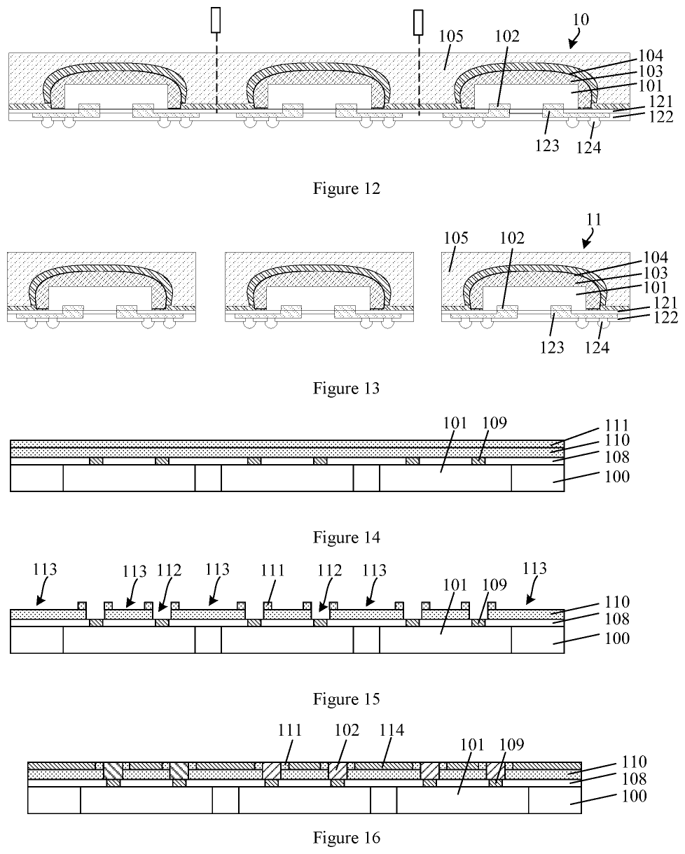

Referring to FIG. 12 and FIG. 13, after forming the external contact structure, the pre-encapsulation panel 10 may be cut to form a plurality of discrete packaging structures 11.

Each packaging structure 11 may include the encapsulation layer 105. The encapsulation layer 105 may contain a semiconductor chip 101 therein. The semiconductor chip 101 may include the functional surface and the non-functional surface opposite to the functional surface. The plurality of pads 102 may be formed on the functional surface. The encapsulation layer 105 may expose the plurality of pads on the functional surface. Each packaging structure 11 may also include the first shielding layer 103 and the second shielding layer 104 disposed between the semiconductor chip 101 and the encapsulation layer 105. The first shielding layer 103 may cover the non-functional surface and the sidewall surface of the semiconductor chip 101, and the surface of the first shielding layer 103 may have an ellipsoidal shape. The second shielding layer 104 may be located between the first shielding layer 103 and the encapsulation layer 105, and may fully cover the surface of the first shielding layer 103 on the non-functional surface and the sidewall surface of the semiconductor chip 101.

Further, each packaging structure may include the external contact structure located on the functional surface of the semiconductor chip and connected to the pad 101. The external contact structure may include the rewiring layer 123 located on the back side of the pre-encapsulation panel 10 and connected to the pad 102, and the external contact element 124 located on the rewiring layer 123 and connected to the rewiring layer 123.

The present disclosure may achieve the mass production of the packaging structures 11 having the first shielding layer 103 and the second shielding layer 104 through the aforementioned semiconductor integrated manufacturing process, and may improve the production efficiency.

### Exemplary Embodiment 2

FIGS. 14-20 illustrate schematic diagrams of semiconductor structures corresponding to certain stages of another method for forming a packaging structure consistent with various disclosed embodiments of the present disclosure. The difference between the Embodiment 2 and the above-mentioned Embodiment 1 may include that a bottom shielding layer may be formed on the functional surface of the semiconductor chip. The bottom shielding layer may cover the entire functional surface of the semiconductor chip. The peripheral edge of the bottom shielding layer may be flush with the peripheral sidewall of the semiconductor chip. The plurality of pads may penetrate through the bottom shielding layer, and the pad may be isolated from the bottom shielding layer through an isolation layer. When forming the first shielding layer, the first shielding layer may be connected to the peripheral edge of the bottom shielding layer.

In the present disclosure, after forming the first shielding layer, the second shielding layer may also be formed on the first shielding layer, such that the second shielding layer may cover the first shielding layer where the thickness is uneven and edge is not well covered. Therefore, the overall shielding layer formed by both the first shielding layer and the second shielding layer may be intact, which may improve the shielding effect. Further, because the bottom shielding layer is also formed on the functional surface of the semiconductor chip, when forming the first shielding layer, the first shielding layer may be connected to the peripheral edge of the bottom shielding layer. Therefore, the semiconductor chip in the packaging structure may be fully or comprehensively covered by the bottom shielding layer and the first shielding layer. The electric field and magnetic field may not enter the packaging structure through the bottom of the packaging structure to bring electromagnetic interference to the semiconductor chip, thereby achieving the all-round electromagnetic shielding for the semiconductor chip, and further improving the electromagnetic shielding effect.

The process of forming the semiconductor chip having the bottom shielding layer may include following. Referring to FIG. 14, a wafer 100 may be provided, and a plurality of semiconductor chips 101 may be formed on the wafer 100. A semiconductor chip 101 may include a top-layer dielectric layer 108 and a top-layer interconnection structure 109 located in the top-layer dielectric layer 108. The semiconductor chip may also include a plurality of semiconductor devices (e.g., transistors, etc.) formed on the surface of the wafer (or semiconductor substrate), and a plurality of interlayer dielectric layers located between the top-layer dielectric layer 108 and the surface of the wafer 100. Each interlayer dielectric layer may contain a corresponding interconnection structure. The interconnection structures in adjacent interlayer dielectric layers may be interconnected, or the interconnection structure may be electrically connected to the semiconductor device. The top-layer interconnection structure 109 in the top-layer dielectric layer 108 may be electrically connected to an interconnection structure in an adjacent interlayer dielectric layer. An isolation layer may be formed on the top-layer dielectric layer 108.

In one embodiment, the isolation layer may have a double-layer stacked structure. The isolation layer may include a first isolation layer 110 and a second isolation layer 111 located on the first isolation layer 110. The first isolation layer 110 may be made of a material different from the second isolation layer 111. The first isolation layer 110 and the second isolation layer 111 may be made of one of silicon oxide, silicon nitride, and silicon oxynitride, which may facilitate to accurately control the depth of subsequently formed second opening, and may prevent over-etching the isolation layer when forming the second opening. Therefore, the second opening may be prevented from exposing a partial surface of a portion of the top-layer interconnection structure 109 in the top-layer dielectric layer 108, and the top-layer interconnection structures 109 may be prevented from being shorted when subsequently forming the bottom shielding layer in the second opening. In certain embodiments, the isolation layer may be a single-layer structure.

Referring to FIG. 15, the isolation layer may be etched to form a plurality of first openings 112 and a second opening 113 surrounding the plurality of first openings 112 in the isolation layer. The remaining isolation layer 111 may be located between the first opening 112 and the second opening 113 to separate the first opening 112 and the second opening 113.

The plurality of first openings 112 may be discrete. The first opening 112 may penetrate through the isolation layer. Each first opening 112 may expose a partial surface of a corresponding top-layer interconnection structure 109. The first opening 112 may be subsequently filled with metal to form the pad.

The second opening 113 may surround the first opening 112, and the second opening 113 may be separated from the first opening 112 by the isolation layer 111. A depth of the second opening 113 may be smaller than a thickness of the isolation layer. A region outside the first opening 112 and the isolation layer 111 surrounding the first opening 112 may correspond to a region of the second opening 113, and, thus the second opening 113 may be connected. When subsequently forming the bottom shielding layer in the second opening 113, the bottom shielding layer may cover the entire region of the functional surface of the semiconductor chip 101 except for the pad (formed in the first opening 112) and the isolation layer surrounding the pad.

When forming the first shielding layer on the non-functional surface and the sidewall surface of the semiconductor chip 101, the first shielding layer may be connected to the peripheral edge of the bottom shielding layer, such that the semiconductor chip in the packaging structure may be fully or comprehensively covered by the bottom shielding layer and the first shielding layer. Therefore, the electric field and magnetic field may not enter the packaging structure through the bottom of the packaging structure to bring electromagnetic interference to the semiconductor chip, thereby achieving the all-round electromagnetic shielding for the semiconductor chip, and further improving the electromagnetic shielding effect.

In one embodiment, the second isolation layer 111 may be etched through a first etching process using the first isolation layer 110 as a stop layer, to form a second opening in the second isolation layer 111. Then, the second isolation layer 111 and the first isolation layer 110 may be etched through a second etching process, to form the first opening in the second isolation layer 111 and the first isolation layer 110. Before performing the first etching process or the second etching process, a corresponding mask layer may be formed on the surface of the second isolation layer 111. It should be noted that the second etching process may be performed before performing the first etching process.

In certain embodiments, when the isolation layer is a single-layer structure, the first opening and the second opening may be respectively formed by performing the etching process twice. By controlling the time-length of the etching process, the depth of the formed second opening may be controlled (the depth of the second opening may be less than the thickness of the isolation layer).

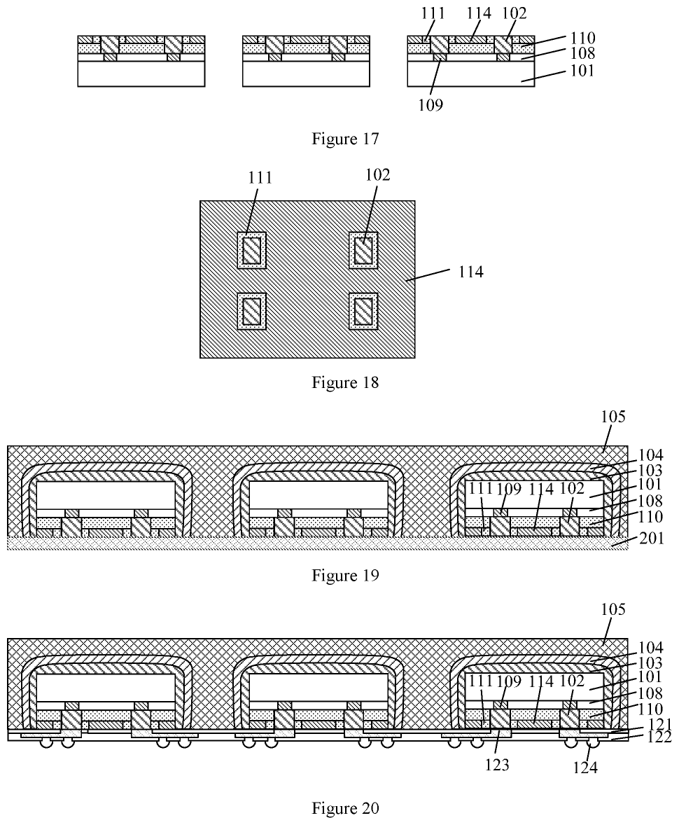

Referring to FIG. 16, the plurality of first openings may be filled with a metal material to form the plurality of pads 102, and the second opening may be filled with a metal material to form the bottom shielding layer 114. Referring to FIG. 17, after forming the pad 102 and the bottom shielding layer 114, the wafer may be cut to form a plurality of discrete semiconductor chips 101 having the bottom shielding layer 114.

In one embodiment, the plurality of pads 102 and the bottom shielding layer 114 may be formed by a same process. The process may include forming a metal material layer in the first and second openings and on the surface of the isolation layer. The metal material layer may be formed by a physical vapor deposition process, a sputtering process, or an electroplating process. The material of the metal material layer may include one or more of aluminum, nickel, tin, tungsten, platinum, copper, titanium, chromium, tantalum, gold, and silver. The process may also include removing the metal material layer above the surface of the isolation layer by performing a planarization process to form the pad 102 in the first opening, and to form the bottom shielding layer 114 in the second opening.

FIG. 18 illustrates a schematic top view of the semiconductor chip 101 in FIG. 17. Referring to FIG. 17 and FIG. 18, the bottom shielding layer 114 may be formed on the functional surface of the semiconductor chip 101. The bottom shielding layer 114 may cover the entire functional surface of the semiconductor chip 101. The peripheral edge of the bottom shielding layer 114 may be flush with the peripheral sidewall of the semiconductor chip 101. The plurality of pads 102 may penetrate through the bottom shielding layer 114. The pad 102 may be isolated from the bottom shielding layer 114 through the isolation layer 111.

The aforementioned process of forming the bottom shielding layer 114 in the present disclosure may be integrated with the existing semiconductor chip manufacturing process. The bottom shielding layer 114 and the pad 102 may be simultaneously formed, which may simplify the manufacturing process, may reduce the process difficulty, and may improve the efficiency.

Referring to FIG. 19, the semiconductor chip 101 having the bottom shielding layer 114 may be adhered to the carrier board 201. The pad 102 and the bottom shielding layer 114 may be in contact with the carrier board 201. A first shielding layer 103 may be formed to cover the non-functional surface and the sidewall surface of the semiconductor chip 101, and the surface of the first shielding layer 103 may have an ellipsoidal shape. A second shielding layer 104 may be formed on the first shielding layer 103. An encapsulation layer 105 may be formed on the second shielding layer 104 and over the carrier board 201 between the semiconductor chips 101.

Referring to FIG. 20, the carrier board 201 (referring to FIG. 19) may be peeled off to form the pre-encapsulation panel. A back side of the pre-encapsulation panel may expose the functional surface of the semiconductor chip. An external contact structure connected to the pad may be formed on the back side of the pre-encapsulation panel. The external contact structure may include the rewiring layer 123 located on the back side of the pre-encapsulation panel and connected to the pad 102, and an external contact element 124 located on the rewiring layer 123 and connected to the rewiring layer 123.

It should be noted that the same or similar structures in the Embodiment 2 and the above-disclosed Embodiment 1 may not be repeated herein, and details may refer to the definitions or descriptions of corresponding parts in the above-disclosed Embodiment 1.

### Exemplary Embodiment 3

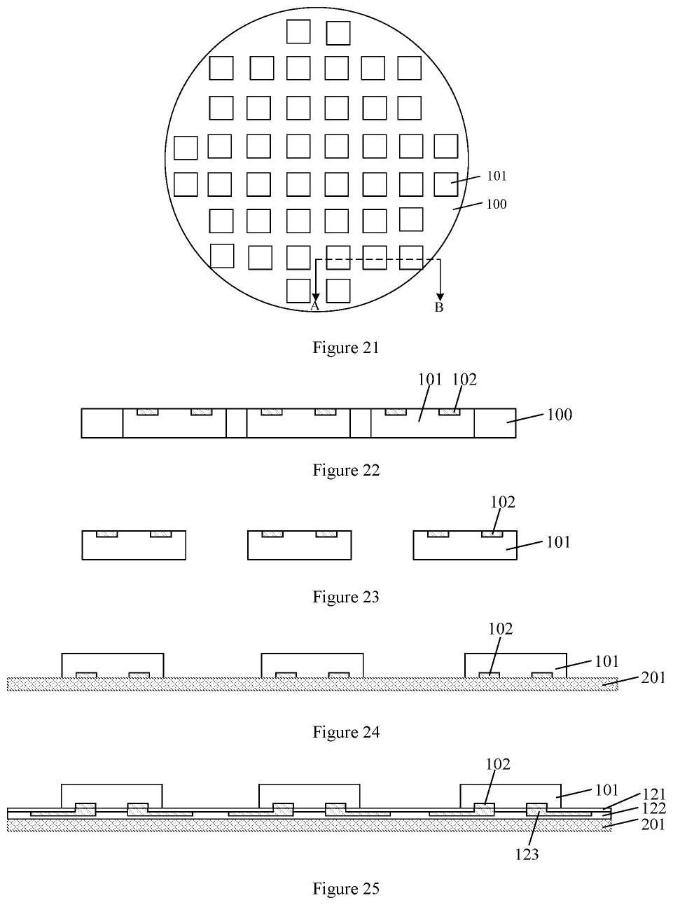

FIGS. 21-33 illustrate schematic diagrams of semiconductor structures corresponding to certain stages of a method for forming a packaging structure consistent with various disclosed embodiments of the present disclosure. FIG. 22 illustrates a schematic AB sectional view of a semiconductor structure in FIG. 21. Referring to FIGS. 21-23, a plurality of semiconductor chips 101 may be provided. Each semiconductor chip 101 may include a functional surface and a non-functional surface opposite to the functional surface. A plurality of pads 102 may be disposed on the functional surface.

An integrated circuit (not illustrated in the Figure) may be formed in/on the functional surface of the semiconductor chip 101. The plurality of pads 102 on the functional surface of the semiconductor chip 101 may be electrically connected to the integrated circuit in the semiconductor chip 101. A pad 102 may serve as a port for the integrated circuit in the semiconductor chip 101 to be electrically connected to an external circuit.

The functional surface of the semiconductor chip 101 may be a surface for forming the integrated circuit, and the non-functional surface may be a surface opposite to the functional surface. The surrounding surface between the functional surface and the non-functional surface may be the sidewall of the semiconductor chip 101.

The semiconductor chip 101 may be formed by a semiconductor integrated manufacturing process. Referring to FIG. 21 and FIG. 22, a wafer 100 may be provided. The wafer 100 may include a plurality of chip regions arranged in rows and columns and a scribe-line region between the chip regions. The plurality of chip regions of the wafer 100 may be used for correspondingly forming the plurality of semiconductor chips 101. The plurality of pads 102 may be formed on the functional surface of the semiconductor chip 101. Referring to FIG. 23, after forming the plurality of pads, the wafer 100 may be cut along the scribe-line to form the plurality of discrete semiconductor chips 101.

In one embodiment, the wafer 100 may be monocrystalline silicon (Si), monocrystalline germanium (Ge), silicon germanium (GeSi), or silicon carbide (SiC). In another embodiment, the wafer may be silicon on insulator (SOI), or germanium on insulator (GOI). In certain embodiments, the wafer may be any other suitable material, e.g., Group III-V compounds, such as allium arsenide (GaAs), etc.

In one embodiment, the integrated circuit in the semiconductor chip 101 may include a plurality of semiconductor devices (e.g., transistor, memory, diode and/or triode, etc.) and an interconnection structure (including metal wire and metal plug) for connecting the semiconductor devices. In one embodiment, the semiconductor chip 101 may be a semiconductor chip that requires electromagnetic shielding.

Referring to FIG. 24, a carrier board 201 may be provided. The functional surface of each semiconductor chip 101 may be adhered to the carrier board 201. The carrier board 201 may provide a supporting platform for subsequent processes. In one embodiment, the carrier board 201 may be a glass carrier board, a silicon carrier board, or a metal carrier board. In another embodiment, the carrier board 201 may be a carrier board made of any other suitable material.

The semiconductor chip 101 may be adhered to the surface of the carrier board 201 by an adhesive layer. The functional surface (or the pad 102) of the semiconductor chip 101 may face toward an adhesive surface of the carrier board 201. The plurality of semiconductor chips 101 may be uniformly adhered to the carrier board 201 in rows and columns.

The adhesive layer may be made of various materials. In one embodiment, the adhesive layer may be made of an UV glue. The UV glue may be a kind of glue material that can be reacted under irradiation of ultraviolet light of special wavelength. The UV glue may be divided into two types according to the change in viscosity after irradiation of ultraviolet light. One kind of the UV glue may be an UV curing glue, that is, the photoinitiator or photosensitizer in the material may absorb ultraviolet light under radiation of ultraviolet light to produce active radicals or cations, which may initiate monomer polymerization, cross-linking and graft chemical reactions to enable the UV curing glue to change from liquid to solid within a few seconds, thereby bonding the surfaces of objects being in contact. Another kind of the UV glue may have substantially high viscosity when not exposed to UV light, and after being exposed to ultraviolet light, the cross-linking chemical bonds in the UV glue may be broken, which may cause the viscosity to significantly decrease or even disappear. The UV glue used for the adhesive layer here may be the latter one. The adhesive layer may be formed by a film-sticking process, a glue-printing process, or a glue-rolling process.

In certain embodiments, the adhesive layer may be made of epoxy glue, polyimide glue, polyethylene glue, benzocyclobutene glue, or polybenzoxazole glue.

In one embodiment, referring to FIG. 25, before adhering the semiconductor chip 101 on the carrier board 201, an insulating layer and a rewiring layer 123 located in the insulating layer may be formed over the carrier board 201. The insulating layer may include a first insulating layer 121 and a second insulating layer 122, and the first insulating layer 121 may be disposed over the second insulating layer 122. The insulating layer (first insulating layer) may expose a partial surface of the rewiring layer 123. The functional surface of each semiconductor chip 101 may be adhered to the rewiring layer 123 over the carrier board 201. In one embodiment, the pad 102 may be adhered to the rewiring layer 123 through a solder layer.

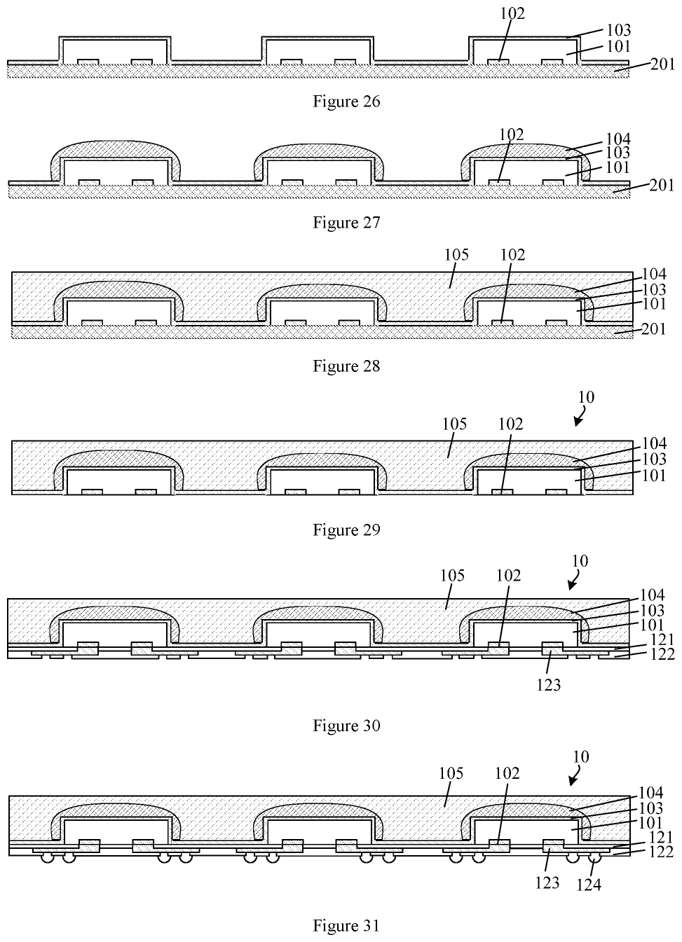

Referring to FIG. 26, a first shielding layer 103 may be formed to cover the non-functional surface and the sidewall surface of the semiconductor chip 101. In one embodiment, the first shielding layer 103 may not only cover the non-functional surface and the sidewall surface of each semiconductor chip 103, but also cover the surface of the carrier board 201 between adjacent semiconductor chips 101. In another embodiment, the first shielding layer 103 may merely cover the non-functional surface and the sidewall surface of each semiconductor chip 101.

In one embodiment, the first shielding layer 103 may be formed by a sputtering process, and the material of the first shielding layer 103 may include copper, tungsten, or aluminum. Because the semiconductor chip 101 has four vertexes (at right angle), and the semiconductor chip 101 has a substantially thick thickness and substantially steep sidewall (the angle between the sidewall and the surface of the carrier board 201 is 90°), the first shielding layer 103 formed by the sputtering process may have uneven thickness and poor edge coverage issues.

In one embodiment, the first shielding layer 103 may be a shielding layer for electric and magnetic fields. The first shielding layer 103 may be used for shielding electric and magnetic fields. The subsequently formed second shielding layer may be a shielding layer for electric and magnetic fields. The second shielding layer may be used for shielding electric and magnetic fields.

The existing shielding layer may not only shield electric field but also shield magnetic field. The existing single-layer shielding layer made of a specific material or multi-layer shielding layer made of a same material or similar materials only has a desired shielding effect on the electric field, and has a substantially poor shielding effect on the magnetic field, thereby affecting the shielding effect of the shielding layer. Therefore, in one embodiment, the first shielding layer 103 may be a magnetic field shielding layer, and the first shielding layer may be used for shielding the magnetic field. The subsequently formed second shielding layer may be an electric field shielding layer, and the second shielding layer may be used for shielding the electric field. In another embodiment, the first shielding layer may be an electric field shielding layer, and the first shielding layer may be used for shielding the electric field. The second shielding layer may be a magnetic field shielding layer, and the second shielding layer may be used for shielding the magnetic field.

The formed first shielding layer and the second shielding layer having the above disclosed structure may shield the electric field and the magnetic field, respectively, thereby improving the shielding effect of the shielding layer. When the first shielding layer 103 is an electric field shielding layer, the material of the first shielding layer 103 (electric field shielding layer) may include copper, tungsten, aluminum. When the first shielding layer 103 is a magnetic field shielding layer, the material of the first shielding layer 103 (magnetic field shielding layer) may include CoFeB alloy, CoFeTa alloy, NiFe alloy, Co, CoFe alloy, CoPt alloy or an alloy of Ni, Co and Fe. The first shielding layer 103 may be formed by a sputtering process, a physical vapor deposition process, an atomic layer deposition process, a chemical vapor deposition, or any other suitable process.

Referring to FIG. 27, a second shielding layer 104 may be formed on the first shielding layer 103. After forming the first shielding layer, the second shielding layer may be formed on the first shielding layer, such that the second shielding layer may cover the first shielding layer where the thickness is uneven and edge is not well covered. Therefore, the overall shielding layer formed by both the first shielding layer and the second shielding layer may be intact, which may improve the shielding effect.

In one embodiment, the second shielding layer 104 may merely be formed on the surface of the first shielding layer 103 covering the non-functional surface and the sidewall surface of the semiconductor chip, and the surface of the second shielding layer 104 may have an ellipsoidal shape. The second shielding layer 104 may be formed by a selective electroplating process, a dispensing process, or a screen-printing process. Thus, the formed second shielding layer 104 may substantially well cover the first shielding layer, and the second shielding layer 104 may be prevented to avoid poor coverage issue, which may further ensure the integrity of the overall shielding layer formed by both the first shielding layer 103 and the second shielding layer 104. Further, the semiconductor chip may not need to be subsequently removed by additional mask and etching processes.

The material of the second shielding layer 104 may include copper, solder or conductive silver paste. In one embodiment, the process for forming the second shielding layer 104 may include following. A mask layer (not illustrated in the Figure) may be first formed on the carrier board 201, and the mask layer may have an opening exposing the first shielding layer 103 on the non-functional surface and the sidewall surface of the semiconductor chip 101. The second shielding layer 104 may be formed in the opening using the first shielding layer 103 as a conductive layer during the electroplating process. Alternatively, solder may be directly brushed into the opening to form the second shielding layer 104. The mask layer may be removed.

In another embodiment, the material of the second shielding layer 104 may be solder or conductive silver paste, and the second shielding layer 104 may be formed by a dispensing process or a screen-printing process. When performing the dispensing process, solder or conductive silver paste may be dispensed on the surface of the first shielding layer 103 formed on the sidewall surface and the non-functional surface of the semiconductor chip 101. When performing the screen-printing process, a portion of the first shielding layer 103 on the carrier board 201 around the semiconductor chip 101 may be first removed, such that the remaining first shielding layer 103 may cover the non-functional surface and sidewall surface of the semiconductor chip, and may be extended to cover a portion of the surface of the carrier board 201 around the semiconductor chip 101. Then a screen with a mesh may be first disposed on the carrier board 201, and each semiconductor chip 101 may be located in a corresponding mesh in the screen. The solder may be brushed into the mesh, and the solder may cover the surface of the first shielding layer 103 formed on the sidewall surface and the non-functional surface of the semiconductor chip 101. The screen may be removed, and the solder may be reflowed to form the second shielding layer 104 on the first shielding layer 103.

In one embodiment, the solder may include one or more of tin, tin silver, tin lead, tin silver copper, tin silver zinc, tin zinc, tin bismuth indium, tin indium, tin gold, tin copper, tin zinc indium, and tin silver antimony.

In one embodiment, the first shielding layer 103 may be a magnetic field shielding layer, and the formed second shielding layer 104 may be an electric field shielding layer. In another embodiment, the first shielding layer 103 may be an electric field shielding layer, and the formed second shielding layer 104 may be a magnetic field shielding layer. The formed first shielding layer and the second shielding layer having the above disclosed structure may shield the electric field and the magnetic field, respectively, thereby improving the shielding effect of the shielding layer.

When the second shielding layer 104 is an electric field shielding layer, the material of the second shielding layer 104 (electric field shielding layer) may include copper, tungsten, aluminum. When the second shielding layer 104 is a magnetic field shielding layer, the material of the second shielding layer 104 (magnetic field shielding layer) may include CoFeB alloy, CoFeTa alloy, NiFe alloy, Co, CoFe alloy, CoPt alloy or an alloy of Ni, Co and Fe. The second shielding layer 104 may be formed by a sputtering process, a physical vapor deposition process, an atomic layer deposition process, a chemical vapor deposition, or any other suitable process.

On one embodiment, after forming the second shielding layer 104, the first shielding layer on the carrier board between adjacent semiconductor chips 101 may be removed by an etching process.

Referring to FIG. 28, an encapsulation layer 105 may be formed over the second shielding layer 104 and the carrier board 201 between the semiconductor chips 101. The encapsulation layer 105 may be used to seal and fix the semiconductor chip 101, which may facilitate to subsequently form a pre-encapsulation panel.

The material of the encapsulation layer 105 may include one or more of epoxy resin, polyimide resin, benzocyclobutene resin, polybenzoxazole resin, polybutylene terephthalate, polycarbonate, polyethylene terephthalate, polyethylene, polypropylene, polyolefin, polyurethane, polyolefin, polyethersulfone, polyamide, polyurethane, ethylene-vinyl acetate, and polyvinyl alcohol. The encapsulation layer 105 may be formed by an injection molding process, a transfer molding process, or any other suitable process.

Referring to FIG. 29, the carrier board 201 (referring to FIG. 28) may be peeled off to form a pre-encapsulation panel 10. A back side of the pre-encapsulation panel 10 may expose the functional surface (and pad) of the semiconductor chip 101. The back side of the pre-encapsulation panel 10 may be the surface in contact with the carrier board 201 (referring to FIG. 28).

The adhesive layer may be removed by chemical etching, mechanical peeling, chemical mechanical polishing (CMP), mechanical grinding, thermal baking, etc., such that the carrier board 201 may be peeled off.

Referring to FIG. 30 and FIG. 31, an external contact structure connected to the pad 102 may be formed on the back side of the pre-encapsulation panel 10. In one embodiment, the external contact structure may include a rewiring layer 123 located on the back side of the pre-encapsulation panel 10 and connected to the pad 102, and an external contact element 124 located on the rewiring layer 123 and connected to the rewiring layer 123. The pad 102 on each semiconductor chip 101 may be connected to a corresponding external contact structure.

In one embodiment, the process of forming the rewiring layer 123 and the external contact element 124 may include following. An insulating layer (first insulating layer) 121 may be formed on the back side of the pre-encapsulation panel 10. The insulating layer (first insulating layer) 121 may have an opening that exposes the surface of the pad 102. The material of the insulating layer (first insulating layer) 121 may include silicon nitride, borosilicate glass, phosphorous silicate glass, or borophosphosilicate glass. The rewiring layer 123 may be formed in the opening and on partial surface of the insulating layer (first insulating layer) 121. An external contact element 124 may be formed on the surface of the rewiring layer outside the opening.

In one embodiment, the external contact element 124 may be a solder ball. In another embodiment, the external contact element 124 may include a metal pillar and a solder ball located on the metal pillar. The process of forming the external contact element 124 may include following. An insulating layer (second insulating layer) 122 may be formed on the insulating layer (first insulating layer) 121 and on the rewiring layer 123. The insulating layer (second insulating layer) 122 may have a second opening exposing partial surface of the rewiring layer 123 on the surface of the insulating layer (first insulating layer) 121. The external contact element 124 may be formed in the second opening.

In one embodiment, a conductive contact structure (not illustrated in the Figure) that electrically connects the first shielding layer 103 and a portion of the rewiring layer 123 may be formed on the insulating layer (first insulating layer) 121, such that the shielding layer may discharge or block external electrostatic interference through the portion of the rewiring layer 123.

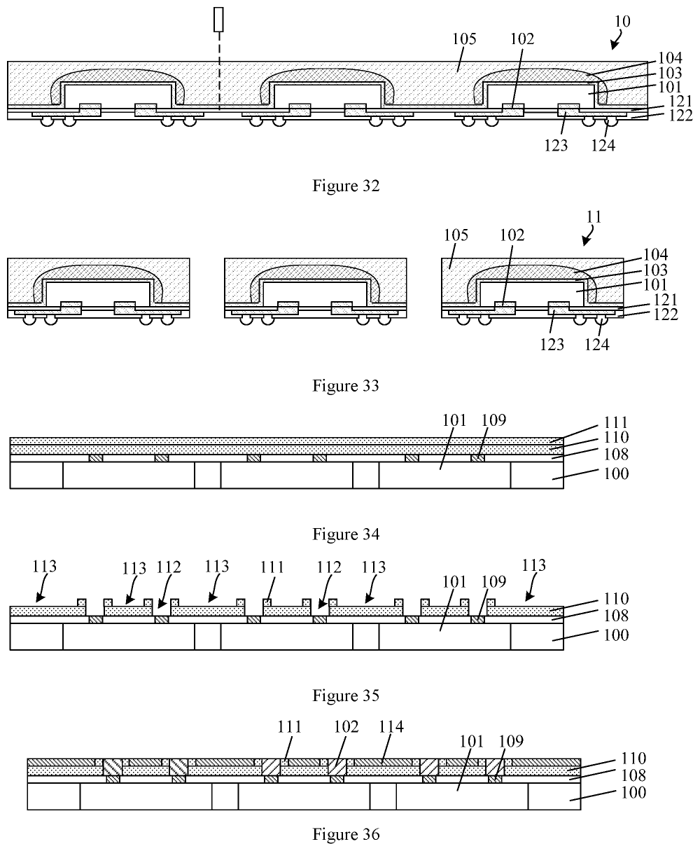

Referring to FIG. 32 and FIG. 33, after forming the external contact structure, the pre-encapsulation panel 10 may be cut to form a plurality of discrete packaging structures 11.

Each packaging structure 11 may include the encapsulation layer 105. The encapsulation layer 105 may contain a semiconductor chip 101 therein. The semiconductor chip 101 may include the functional surface and the non-functional surface opposite to the functional surface. The plurality of pads 102 may be formed on the functional surface. The encapsulation layer 105 may expose the plurality of pads on the functional surface. Each packaging structure 11 may also include the first shielding layer 103 and the second shielding layer 104 disposed between the semiconductor chip 101 and the encapsulation layer 105. The first shielding layer 103 may cover the non-functional surface and the sidewall surface of the semiconductor chip 101. The second shielding layer 104 may be located between the first shielding layer 103 and the encapsulation layer 105, and may fully cover the surface of the first shielding layer 103 on the non-functional surface and the sidewall surface of the semiconductor chip 101.

Further, each packaging structure may include the external contact structure located on the functional surface of the semiconductor chip and connected to the pad 101. The external contact structure may include the rewiring layer 123 located on the back side of the pre-encapsulation panel 10 and connected to the pad 102, and the external contact element 124 located on the rewiring layer 123 and connected to the rewiring layer 123.

The present disclosure may achieve the mass production of the packaging structures 11 having the first shielding layer 103 and the second shielding layer 104 through the aforementioned semiconductor integrated manufacturing process, and may improve the production efficiency.

### Exemplary Embodiment 4

FIGS. 34-40 illustrate schematic diagrams of semiconductor structures corresponding to certain stages of another method for forming a packaging structure consistent with various disclosed embodiments of the present disclosure. The difference between the Embodiment 4 and the above-mentioned Embodiment 3 may include that a bottom shielding layer may be formed on the functional surface of the semiconductor chip. The bottom shielding layer may cover the entire functional surface of the semiconductor chip. The peripheral edge of the bottom shielding layer may be flush with the peripheral sidewall of the semiconductor chip. The plurality of pads may penetrate through the bottom shielding layer, and the pad may be isolated from the bottom shielding layer through an isolation layer. When forming the first shielding layer, the first shielding layer may be connected to the peripheral edge of the bottom shielding layer.

In the present disclosure, after forming the first shielding layer, the second shielding layer may also be formed on the first shielding layer, such that the second shielding layer may cover the first shielding layer where the thickness is uneven and edge is not well covered. Therefore, the overall shielding layer formed by both the first shielding layer and the second shielding layer may be intact, which may improve the shielding effect. Further, because the bottom shielding layer is also formed on the functional surface of the semiconductor chip, when forming the first shielding layer, the first shielding layer may be connected to the peripheral edge of the bottom shielding layer. Therefore, the semiconductor chip in the packaging structure may be fully or comprehensively covered by the bottom shielding layer and the first shielding layer. The electric field and magnetic field may not enter the packaging structure through the bottom of the packaging structure to bring electromagnetic interference to the semiconductor chip, thereby achieving the all-round electromagnetic shielding for the semiconductor chip, and further improving the electromagnetic shielding effect.

The process of forming the semiconductor chip having the bottom shielding layer may include following. Referring to FIG. 34, a wafer 100 may be provided, and a plurality of semiconductor chips 101 may be formed on the wafer 100. A semiconductor chip 101 may include a top-layer dielectric layer 108 and a top-layer interconnection structure 109 located in the top-layer dielectric layer 108. The semiconductor chip may also include a plurality of semiconductor devices (e.g., transistors, etc.) formed on the surface of the wafer (or semiconductor substrate), and a plurality of interlayer dielectric layers located between the top-layer dielectric layer 108 and the surface of the wafer 100. Each interlayer dielectric layer may contain a corresponding interconnection structure. The interconnection structures in adjacent interlayer dielectric layers may be interconnected, or the interconnection structure may be electrically connected to the semiconductor device. The top-layer interconnection structure 109 in the top-layer dielectric layer 108 may be electrically connected to an interconnection structure in an adjacent interlayer dielectric layer. An isolation layer may be formed on the top-layer dielectric layer 108.

In one embodiment, the isolation layer may have a double-layer stacked structure. The isolation layer may include a first isolation layer 110 and a second isolation layer 111 located on the first isolation layer 110. The first isolation layer 110 may be made of a material different from the second isolation layer 111. The first isolation layer 110 and the second isolation layer 111 may be made of one of silicon oxide, silicon nitride, and silicon oxynitride, which may facilitate to accurately control the depth of subsequently formed second opening, and may prevent over-etching the isolation layer when forming the second opening. Therefore, the second opening may be prevented from exposing a partial surface of a portion of the top-layer interconnection structure 109 in the top-layer dielectric layer 108, and the top-layer interconnection structures 109 may be prevented from being shorted when subsequently forming the bottom shielding layer in the second opening. In certain embodiments, the isolation layer may be a single-layer structure.

Referring to FIG. 35, the isolation layer may be etched to form a plurality of first openings 112 and a second opening 113 surrounding the plurality of first openings 112 in the isolation layer. The remaining isolation layer 111 may be located between the first opening 112 and the second opening 113 to separate the first opening 112 and the second opening 113.

The plurality of first openings 112 may be discrete. The first opening 112 may penetrate through the isolation layer. Each first opening 112 may expose a partial surface of a corresponding top-layer interconnection structure 109. The first opening 112 may be subsequently filled with metal to form the pad.

The second opening 113 may surround the first opening 112, and the second opening 113 may be separated from the first opening 112 by the isolation layer 111. A depth of the second opening 113 may be smaller than a thickness of the isolation layer. A region outside the first opening 112 and the isolation layer 111 surrounding the first opening 112 may correspond to a region of the second opening 113, and, thus the second opening 113 may be connected. When subsequently forming the bottom shielding layer in the second opening 113, the bottom shielding layer may cover the entire region of the functional surface of the semiconductor chip 101 except for the pad (formed in the first opening 112) and the isolation layer surrounding the pad.

When forming the first shielding layer on the non-functional surface and the sidewall surface of the semiconductor chip 101, the first shielding layer may be connected to the peripheral edge of the bottom shielding layer, such that the semiconductor chip in the packaging structure may be fully or comprehensively covered by the bottom shielding layer and the first shielding layer. Therefore, the electric field and magnetic field may not enter the packaging structure through the bottom of the packaging structure to bring electromagnetic interference to the semiconductor chip, thereby achieving the all-round electromagnetic shielding for the semiconductor chip, and further improving the electromagnetic shielding effect.

In one embodiment, the second isolation layer 111 may be etched through a first etching process using the first isolation layer 110 as a stop layer, to form a second opening in the second isolation layer 111. Then, the second isolation layer 111 and the first isolation layer 110 may be etched through a second etching process, to form the first opening in the second isolation layer 111 and the first isolation layer 110. Before performing the first etching process or the second etching process, a corresponding mask layer may be formed on the surface of the second isolation layer 111. It should be noted that the second etching process may be performed before performing the first etching process.

In certain embodiments, when the isolation layer is a single-layer structure, the first opening and the second opening may be respectively formed by performing the etching process twice. By controlling the time-length of the etching process, the depth of the formed second opening may be controlled (the depth of the second opening may be less than the thickness of the isolation layer).

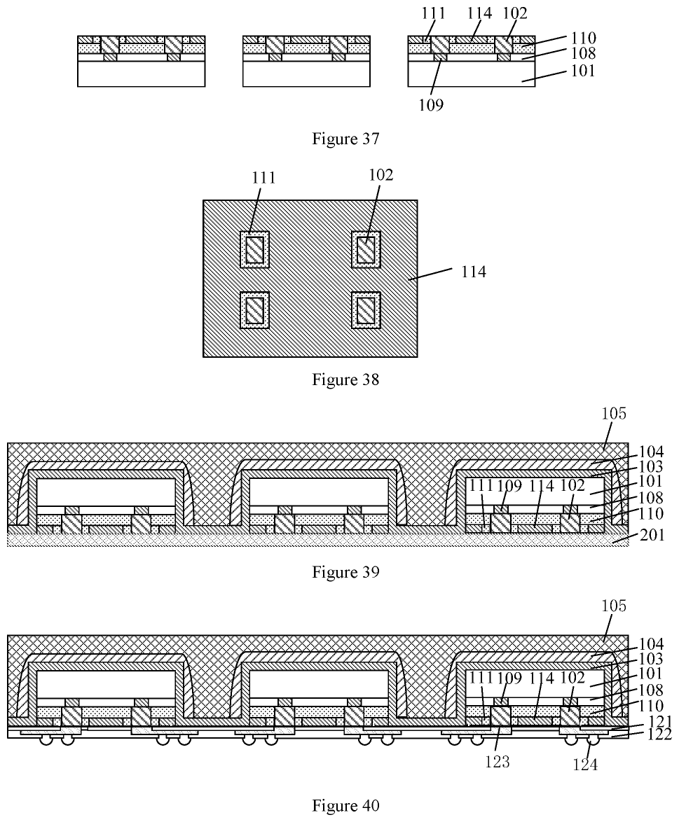

Referring to FIG. 36, the plurality of first openings may be filled with a metal material to form the plurality of pads 102, and the second opening may be filled with a metal material to form the bottom shielding layer 114. Referring to FIG. 37, after forming the pad 102 and the bottom shielding layer 114, the wafer may be cut to form a plurality of discrete semiconductor chips 101 having the bottom shielding layer 114.

In one embodiment, the plurality of pads 102 and the bottom shielding layer 114 may be formed by a same process. The process may include forming a metal material layer in the first and second openings and on the surface of the isolation layer. The metal material layer may be formed by a physical vapor deposition process, a sputtering process, or an electroplating process. The material of the metal material layer may include one or more of aluminum, nickel, tin, tungsten, platinum, copper, titanium, chromium, tantalum, gold, and silver. The process may also include removing the metal material layer above the surface of the isolation layer by performing a planarization process to form the pad 102 in the first opening, and to form the bottom shielding layer 114 in the second opening.

FIG. 38 illustrates a schematic top view of the semiconductor chip 101 in FIG. 37. Referring to FIG. 37 and FIG. 38, the bottom shielding layer 114 may be formed on the functional surface of the semiconductor chip 101. The bottom shielding layer 114 may cover the entire functional surface of the semiconductor chip 101. The peripheral edge of the bottom shielding layer 114 may be flush with the peripheral sidewall of the semiconductor chip 101. The plurality of pads 102 may penetrate through the bottom shielding layer 114. The pad 102 may be isolated from the bottom shielding layer 114 through the isolation layer 111. The aforementioned process of forming the bottom shielding layer 114 in the present disclosure may be integrated with the existing semiconductor chip manufacturing process. The bottom shielding layer 114 and the pad 102 may be simultaneously formed, which may simplify the manufacturing process, may reduce the process difficulty, and may improve the efficiency.

Referring to FIG. 39, the semiconductor chip 101 having the bottom shielding layer 114 may be adhered to the carrier board 201. The pad 102 and the bottom shielding layer 114 may be in contact with the carrier board 201. A first shielding layer 103 may be formed to cover the non-functional surface and the sidewall surface of the semiconductor chip 101. A second shielding layer 104 may be formed on the first shielding layer 103. An encapsulation layer 105 may be formed on the second shielding layer 104 and over the carrier board 201 between the semiconductor chips 101.

Referring to FIG. 40, the carrier board 201 (referring to FIG. 39) may be peeled off to form the pre-encapsulation panel. A back side of the pre-encapsulation panel may expose the functional surface of the semiconductor chip. An external contact structure connected to the pad may be formed on the back side of the pre-encapsulation panel. The external contact structure may include the rewiring layer 123 located on the back side of the pre-encapsulation panel and connected to the pad 102, and an external contact element 124 located on the rewiring layer 123 and connected to the rewiring layer 123.

It should be noted that the same or similar structures in the Embodiment 4 and the above-disclosed Embodiment 3 may not be repeated herein, and details may refer to the definitions or descriptions of corresponding parts in the above-disclosed Embodiment 3.

### Exemplary Embodiment 5

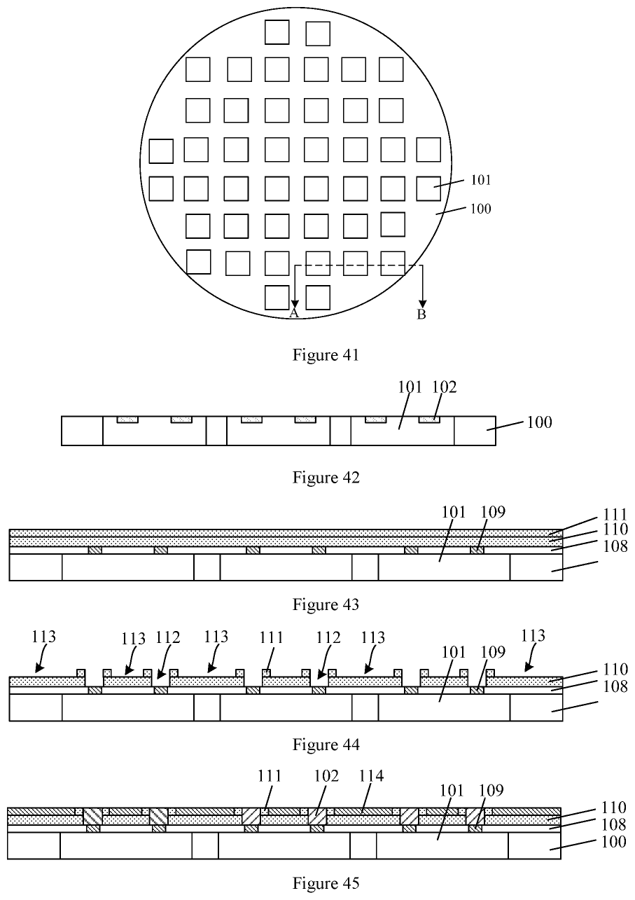

FIGS. 41-58 illustrate schematic diagrams of semiconductor structures corresponding to certain stages of a method for forming a packaging structure consistent with various disclosed embodiments of the present disclosure. FIG. 42 illustrates a schematic AB sectional view of a semiconductor structure in FIG. 41. Referring to FIGS. 41-46, a plurality of semiconductor chips 101 may be provided. Each semiconductor chip 101 may include a functional surface and a non-functional surface opposite to the functional surface. A plurality of pads 102 may be formed on the functional surface. Further, a bottom shielding layer 114 may be formed on the functional surface of the semiconductor chip 101. The bottom shielding layer 114 may cover the entire functional surface of the semiconductor chip 101, and the peripheral edge of the bottom shielding layer 114 may be flush with the surrounding sidewall of the semiconductor chip 101. The plurality of pads 102 may penetrate through the bottom shielding layer, and the pad 102 may be isolated from the bottom shielding layer 114 by an isolation layer 111.

An integrated circuit (not illustrated in the Figure) may be formed in/on the functional surface of the semiconductor chip 101. The plurality of pads 102 on the functional surface of the semiconductor chip 101 may be electrically connected to the integrated circuit in the semiconductor chip 101. A pad 102 may serve as a port for the integrated circuit in the semiconductor chip 101 to be electrically connected to an external circuit.

In one embodiment, the integrated circuit in the semiconductor chip 101 may include a plurality of semiconductor devices (e.g., transistor, memory, diode and/or triode, etc.) and an interconnection structure (including metal wire and metal plug) for connecting the semiconductor devices. In one embodiment, the semiconductor chip 101 may be a semiconductor chip that requires electromagnetic shielding.

The functional surface of the semiconductor chip 101 may be a surface for forming the integrated circuit, and the non-functional surface may be a surface opposite to the functional surface. The surrounding surface between the functional surface and the non-functional surface may be the sidewall of the semiconductor chip 101.

The semiconductor chip 101 may be formed by a semiconductor integrated manufacturing process. Referring to FIGS. 41-43, a wafer 100 may be provided. The wafer 100 may include a plurality of chip regions arranged in rows and columns and a scribe-line region between the chip regions. The plurality of chip regions of the wafer 100 may be used for correspondingly forming the plurality of semiconductor chips 101.

The semiconductor chip 101 may include a top-layer dielectric layer 108 and a top-layer interconnection structure 109 located in the top-layer dielectric layer 108. The semiconductor chip may also include a plurality of semiconductor devices (e.g., transistors, etc.) formed on the surface of the wafer (or semiconductor substrate), and a plurality of interlayer dielectric layers located between the top-layer dielectric layer 108 and the surface of the wafer 100. Each interlayer dielectric layer may contain a corresponding interconnection structure. The interconnection structures in adjacent interlayer dielectric layers may be interconnected, or the interconnection structure may be electrically connected to the semiconductor device. The top-layer interconnection structure 109 in the top-layer dielectric layer 108 may be electrically connected to an interconnection structure in an adjacent interlayer dielectric layer. An isolation layer may be formed on the top-layer dielectric layer 108.

In one embodiment, the wafer 100 may be monocrystalline silicon (Si), monocrystalline germanium (Ge), silicon germanium (GeSi), or silicon carbide (SiC). In another embodiment, the wafer may be silicon on insulator (SOI), or germanium on insulator (GOI). In certain embodiments, the wafer may be any other suitable material, e.g., Group III-V compounds, such as allium arsenide (GaAs), etc.

In one embodiment, the isolation layer may have a double-layer stacked structure. The isolation layer may include a first isolation layer 110 and a second isolation layer 111 located on the first isolation layer 110. The first isolation layer 110 may be made of a material different from the second isolation layer 111. The first isolation layer 110 and the second isolation layer 111 may be made of one of silicon oxide, silicon nitride, and silicon oxynitride, which may facilitate to accurately control the depth of subsequently formed second opening, and may prevent over-etching the isolation layer when forming the second opening. Therefore, the second opening may be prevented from exposing a partial surface of a portion of the top-layer interconnection structure 109 in the top-layer dielectric layer 108, and the top-layer interconnection structures 109 may be prevented from being shorted when subsequently forming the bottom shielding layer in the second opening. In certain embodiments, the isolation layer may be a single-layer structure.

Referring to FIG. 44, the isolation layer may be etched to form a plurality of first openings 112 and a second opening 113 surrounding the plurality of first openings 112 in the isolation layer. The remaining isolation layer 111 may be located between the first opening 112 and the second opening 113 to separate the first opening 112 and the second opening 113.

The plurality of first openings 112 may be discrete. The first opening 112 may penetrate through the isolation layer. Each first opening 112 may expose a partial surface of a corresponding top-layer interconnection structure 109. The first opening 112 may be subsequently filled with metal to form the pad.

The second opening 113 may surround the first opening 112, and the second opening 113 may be separated from the first opening 112 by the isolation layer 111. A depth of the second opening 113 may be smaller than a thickness of the isolation layer. A region outside the first opening 112 and the isolation layer 111 surrounding the first opening 112 may correspond to a region of the second opening 113, and, thus the second opening 113 may be connected. When subsequently forming the bottom shielding layer in the second opening 113, the bottom shielding layer may cover the entire region of the functional surface of the semiconductor chip 101 except for the pad (formed in the first opening 112) and the isolation layer surrounding the pad.

When forming the first shielding layer on the non-functional surface and the sidewall surface of the semiconductor chip 101, the first shielding layer may be connected to the peripheral edge of the bottom shielding layer, such that the semiconductor chip in the packaging structure may be fully or comprehensively covered by the bottom shielding layer and the first shielding layer. Therefore, the electric field and magnetic field may not enter the packaging structure through the bottom of the packaging structure to bring electromagnetic interference to the semiconductor chip, thereby achieving the all-round electromagnetic shielding for the semiconductor chip, and further improving the electromagnetic shielding effect.

In one embodiment, the second isolation layer 111 may be etched through a first etching process using the first isolation layer 110 as a stop layer, to form a second opening in the second isolation layer 111. Then, the second isolation layer 111 and the first isolation layer 110 may be etched through a second etching process, to form the first opening in the second isolation layer 111 and the first isolation layer 110. Before performing the first etching process or the second etching process, a corresponding mask layer may be formed on the surface of the second isolation layer 111. It should be noted that the second etching process may be performed before performing the first etching process.

In certain embodiments, when the isolation layer is a single-layer structure, the first opening and the second opening may be respectively formed by performing the etching process twice. By controlling the time-length of the etching process, the depth of the formed second opening may be controlled (the depth of the second opening may be less than the thickness of the isolation layer).

Referring to FIG. 45, the plurality of first openings may be filled with a metal material to form the plurality of pads, and the second opening may be filled with a metal material to form the bottom shielding layer 114.

In one embodiment, the plurality of pads 102 and the bottom shielding layer 114 may be formed by a same process. The process may include forming a metal material layer in the first and second openings and on the surface of the isolation layer. The metal material layer may be formed by a physical vapor deposition process, a sputtering process, or an electroplating process. The material of the metal material layer may include one or more of aluminum, nickel, tin, tungsten, platinum, copper, titanium, chromium, tantalum, gold, and silver. The process may also include removing the metal material layer above the surface of the isolation layer by performing a planarization process to form the pad 102 in the first opening, and to form the bottom shielding layer 114 in the second opening.

In one embodiment, after forming the pad 102, the wafer may be directly cut to form the plurality of discrete semiconductor chips 101. In another embodiment, after forming the pad 102, a metal bump may be formed on the pad. After forming the metal bump, the wafer may be cut to form the plurality of discrete semiconductor chips 101.

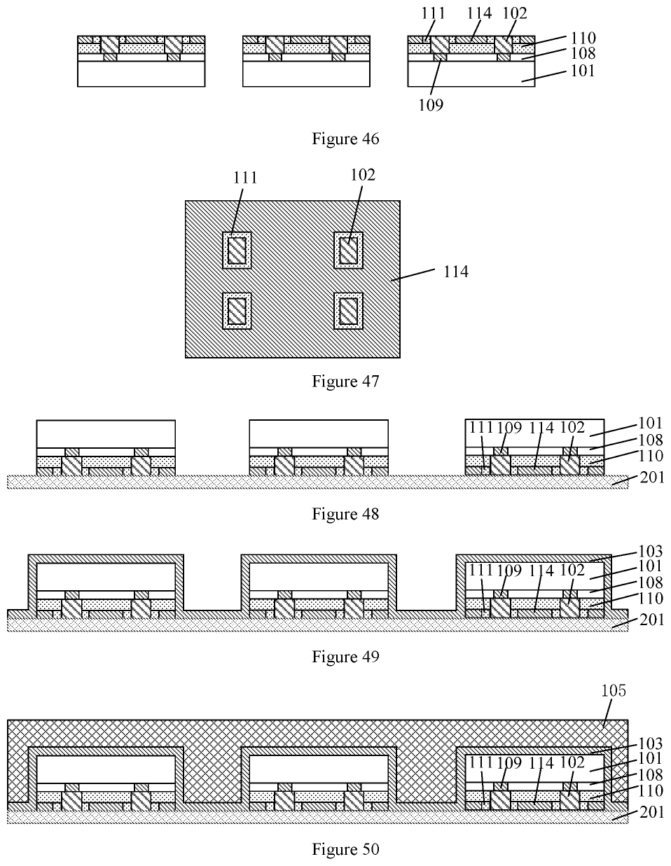

Referring to FIG. 45 and FIG. 46, after forming the pad 102 and the bottom shielding layer 114, the wafer may be cut to form a plurality of discrete semiconductor chips 101 having the bottom shielding layer 114.

FIG. 47 illustrates a schematic top view of the semiconductor chip 101 in FIG. 46. Referring to FIG. 46 and FIG. 47, the bottom shielding layer 114 may be formed on the functional surface of the discrete semiconductor chip 101. The bottom shielding layer 114 may cover the entire functional surface of the semiconductor chip 101. The peripheral edge of the bottom shielding layer 114 may be flush with the peripheral sidewall of the semiconductor chip 101. The plurality of pads 102 may penetrate through the bottom shielding layer 114. The pad 102 may be isolated from the bottom shielding layer 114 through the isolation layer 111.

The aforementioned process of forming the bottom shielding layer 114 in the present disclosure may be integrated with the existing semiconductor chip manufacturing process. The bottom shielding layer 114 and the pad 102 may be simultaneously formed, which may simplify the manufacturing process, may reduce the process difficulty, and may improve the efficiency.

Referring to FIG. 48, a carrier board 201 may be provided. The functional surface of each semiconductor chip 101 may be adhered to the carrier board 201. The pad 102 and the bottom shielding layer 114 may be in contact with the carrier board 201. The carrier board 201 may provide a supporting platform for subsequent processes. In one embodiment, the carrier board 201 may be a glass carrier board, a silicon carrier board, or a metal carrier board. In another embodiment, the carrier board 201 may be a carrier board made of any other suitable material.

The semiconductor chip 101 may be adhered to the surface of the carrier board 201 by an adhesive layer. The functional surface (or the pad 102) of the semiconductor chip 101 may face toward an adhesive surface of the carrier board 201. The plurality of semiconductor chips 101 may be uniformly adhered to the carrier board 201 in rows and columns.

The adhesive layer may be made of various materials. In one embodiment, the adhesive layer may be made of an UV glue. The UV glue may be a kind of glue material that can be reacted under irradiation of ultraviolet light of special wavelength. The UV glue may be divided into two types according to the change in viscosity after irradiation of ultraviolet light. One kind of the UV glue may be an UV curing glue, that is, the photoinitiator or photosensitizer in the material may absorb ultraviolet light under radiation of ultraviolet light to produce active radicals or cations, which may initiate monomer polymerization, cross-linking and graft chemical reactions to enable the UV curing glue to change from liquid to solid within a few seconds, thereby bonding the surfaces of objects being in contact. Another kind of the UV glue may have substantially high viscosity when not exposed to UV light, and after being exposed to ultraviolet light, the cross-linking chemical bonds in the UV glue may be broken, which may cause the viscosity to significantly decrease or even disappear. The UV glue used for the adhesive layer here may be the latter one. The adhesive layer may be formed by a film-sticking process, a glue-printing process, or a glue-rolling process.

In certain embodiments, the adhesive layer may be made of epoxy glue, polyimide glue, polyethylene glue, benzocyclobutene glue, or polybenzoxazole glue.

In one embodiment, before adhering the semiconductor chip on the carrier board, an insulating layer and a rewiring layer located in the insulating layer may be formed over the carrier board. The insulating layer may include a first insulating layer and a second insulating layer, and the first insulating layer may be disposed over the second insulating layer. The insulating layer (first insulating layer) may expose a partial surface of the rewiring layer. The functional surface of each semiconductor chip may be adhered to the rewiring layer over the carrier board. In one embodiment, the pad may be adhered to the rewiring layer through a solder layer.

Referring to FIG. 49, a first shielding layer 103 may be formed to cover the non-functional surface and the sidewall surface of the semiconductor chip 101. When forming the first shielding layer 103, the first shielding layer 103 may be connected to the peripheral edge of the bottom shielding layer 114.

In one embodiment, the bottom shielding layer 114 may be formed on the functional surface of the semiconductor chip 101. When forming the first shielding layer 103, the first shielding layer 103 may be connected to the peripheral edge of the bottom shielding layer 114, such that the semiconductor chip in the packaging structure may be fully or comprehensively covered by the bottom shielding layer 114 and the first shielding layer 103. Therefore, the electric field and magnetic field may not enter the packaging structure through the bottom of the packaging structure to bring electromagnetic interference to the semiconductor chip, thereby achieving the all-round electromagnetic shielding for the semiconductor chip, and further improving the electromagnetic shielding effect

In one embodiment, the first shielding layer 103 may not only cover the non-functional surface and the sidewall surface of each semiconductor chip 103, but also cover the surface of the carrier board 201 between adjacent semiconductor chips 101. In another embodiment, the first shielding layer 103 may merely cover the non-functional surface and the sidewall surface of each semiconductor chip 101.

In certain embodiments, the first shielding layer 103 may merely cover the non-functional surface and the sidewall surface of the semiconductor chip. The first shielding layer 103 may be formed by a selective electroplating process, a dispensing process, or a screen-printing process. Thus, the first shielding layer may substantially well cover the functional surface and the sidewall surface of the semiconductor chip, and the first shielding layer 103 may be prevented to avoid uneven thickness or poor coverage issue. The material of the first shielding layer 103 may include copper, solder or conductive silver paste.

Referring to FIG. 50, an encapsulation layer 105 may be formed over the first shielding layer 103 and the carrier board 201 between the semiconductor chips 101. The encapsulation layer 105 may be used to seal and fix the semiconductor chip 101, which may facilitate to subsequently form a pre-encapsulation panel.

The material of the encapsulation layer 105 may include one or more of epoxy resin, polyimide resin, benzocyclobutene resin, polybenzoxazole resin, polybutylene terephthalate, polycarbonate, polyethylene terephthalate, polyethylene, polypropylene, polyolefin, polyurethane, polyolefin, polyethersulfone, polyamide, polyurethane, ethylene-vinyl acetate, and polyvinyl alcohol. The encapsulation layer 105 may be formed by an injection molding process, a transfer molding process, or any other suitable process.

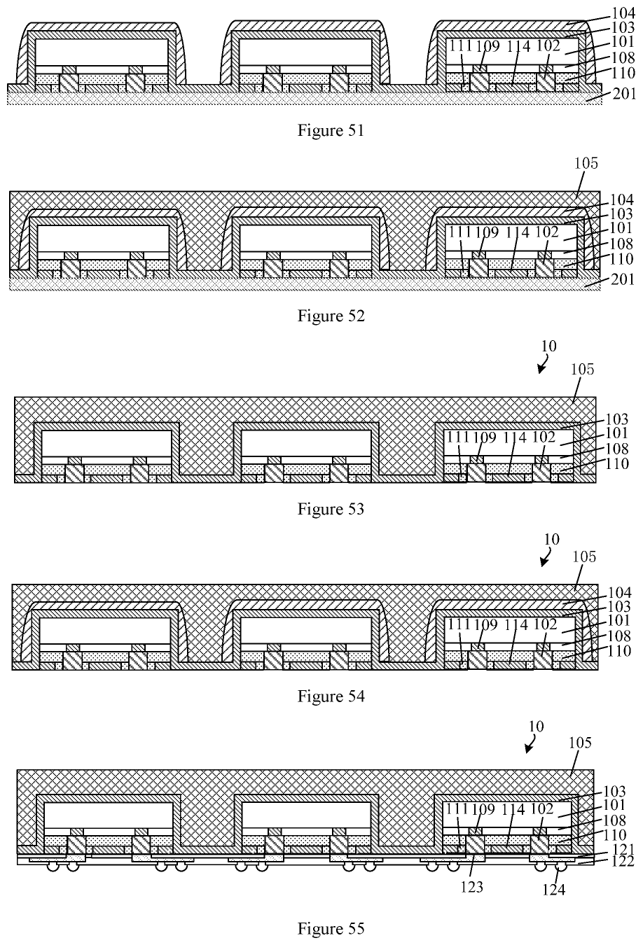

In certain embodiments, referring to FIG. 51 and FIG. 52, before forming the encapsulation layer 105, a second shielding layer 104 may be formed on the first shielding layer 103. After forming the second shielding layer, the encapsulation layer 105 may be formed over the second shielding layer 104 and the carrier board 201 between the semiconductor chips 101.

In one embodiment, when forming the first shielding layer 103 by a sputtering process, because the semiconductor chip 101 has four vertexes (or sharp corners), and the semiconductor chip 101 has a substantially thick thickness and substantially steep sidewall, the first shielding layer 103 formed by the sputtering process may have uneven thickness and poor edge coverage issues, which may affect the shielding performance of the shielding layer.

After forming the first shielding layer 103, the second shielding layer 104 may be formed on the first shielding layer, such that the second shielding layer may cover the first shielding layer where the thickness is uneven and edge is not well covered. Therefore, the overall shielding layer formed by the first shielding layer 103, the second shielding layer 104 and the bottom shielding layer 114 may be substantially intact, which may improve the shielding effect.

In one embodiment, the second shielding layer 104 may merely be formed on the surface of the first shielding layer 103 covering the non-functional surface and the sidewall surface of the semiconductor chip, and the surface of the second shielding layer 104 may have an ellipsoidal shape. The second shielding layer 104 may be formed by a selective electroplating process, a dispensing process, or a screen-printing process. Thus, the formed second shielding layer 104 may substantially well cover the first shielding layer, and the second shielding layer 104 may be prevented to avoid poor coverage issue, which may further ensure the integrity of the overall shielding layer formed by both the first shielding layer 103 and the second shielding layer 104. Further, the semiconductor chip may not need to be subsequently removed by additional mask and etching processes.

The material of the second shielding layer 104 may include copper, solder or conductive silver paste. In one embodiment, the process for forming the second shielding layer 104 may include following. A mask layer (not illustrated in the Figure) may be first formed on the carrier board 201, and the mask layer may have an opening exposing the first shielding layer 103 on the non-functional surface and the sidewall surface of the semiconductor chip 101. The second shielding layer 104 may be formed in the opening using the first shielding layer 103 as a conductive layer during the electroplating process. Alternatively, solder may be directly brushed into the opening to form the second shielding layer 104. The mask layer may be removed.

In another embodiment, the material of the second shielding layer 104 may be solder or conductive silver paste, and the second shielding layer 104 may be formed by a dispensing process or a screen-printing process. When performing the dispensing process, solder or conductive silver paste may be dispensed on the surface of the first shielding layer 103 formed on the sidewall surface and the non-functional surface of the semiconductor chip 101. When performing the screen-printing process, a portion of the first shielding layer 103 on the carrier board 201 around the semiconductor chip 101 may be first removed, such that the remaining first shielding layer 103 may cover the non-functional surface and sidewall surface of the semiconductor chip, and may be extended to cover a portion of the surface of the carrier board 201 around the semiconductor chip 101. Then a screen with a mesh may be first disposed on the carrier board 201, and each semiconductor chip 101 may be located in a corresponding mesh in the screen. The solder may be brushed into the mesh, and the solder may cover the surface of the first shielding layer 103 formed on the sidewall surface and the non-functional surface of the semiconductor chip 101. The screen may be removed, and the solder may be reflowed to form the second shielding layer 104 on the first shielding layer 103.

In one embodiment, the solder may include one or more of tin, tin silver, tin lead, tin silver copper, tin silver zinc, tin zinc, tin bismuth indium, tin indium, tin gold, tin copper, tin zinc indium, and tin silver antimony.

In one embodiment, the first shielding layer 103 may be a shielding layer for electric and magnetic fields. The first shielding layer 103 may be used for shielding electric and magnetic fields. The subsequently formed second shielding layer may be a shielding layer for electric and magnetic fields. The second shielding layer may be used for shielding electric and magnetic fields.

The existing shielding layer may not only shield electric field but also shield magnetic field. The existing single-layer shielding layer made of a specific material or multi-layer shielding layer made of a same material or similar materials only has a desired shielding effect on the electric field, and has a substantially poor shielding effect on the magnetic field, thereby affecting the shielding effect of the shielding layer. Therefore, in one embodiment, the first shielding layer 103 may be a magnetic field shielding layer, and the first shielding layer may be used for shielding the magnetic field. The second shielding layer 104 may be an electric field shielding layer, and the second shielding layer 104 may be used for shielding the electric field. In another embodiment, the first shielding layer 103 may be an electric field shielding layer, and the first shielding layer 103 may be used for shielding the electric field. The second shielding layer 104 may be a magnetic field shielding layer, and the second shielding layer 104 may be used for shielding the magnetic field.

The formed first shielding layer 103 and the second shielding layer 104 having the above disclosed structure may shield the electric field and the magnetic field, respectively, thereby further improving the shielding effect of the shielding layer. When the first shielding layer 103 is an electric field shielding layer, the material of the first shielding layer 103 (electric field shielding layer) may include copper, tungsten, aluminum. When the first shielding layer 103 is a magnetic field shielding layer, the material of the first shielding layer 103 (magnetic field shielding layer) may include CoFeB alloy, CoFeTa alloy, NiFe alloy, Co, CoFe alloy, CoPt alloy or an alloy of Ni, Co and Fe. The first shielding layer 103 may be formed by a sputtering process, a physical vapor deposition process, an atomic layer deposition process, a chemical vapor deposition, or any other suitable process.

When the second shielding layer 104 is an electric field shielding layer, the material of the second shielding layer 104 (electric field shielding layer) may include copper, tungsten, aluminum. When the second shielding layer 104 is a magnetic field shielding layer, the material of the second shielding layer 104 (magnetic field shielding layer) may include CoFeB alloy, CoFeTa alloy, NiFe alloy, Co, CoFe alloy, CoPt alloy or an alloy of Ni, Co and Fe. The second shielding layer 104 may be formed by a sputtering process, a physical vapor deposition process, an atomic layer deposition process, a chemical vapor deposition, or any other suitable process.

Referring to FIG. 53 (on the basis of FIG. 50) or FIG. 54 (on the basis of FIG. 52), the carrier board 201 may be peeled off to form a pre-encapsulation panel 10. A back side of the pre-encapsulation panel 10 may expose the functional surface (and pad) of the semiconductor chip 101. The back side of the pre-encapsulation panel 10 may be the surface in contact with the carrier board 201.

The adhesive layer may be removed by chemical etching, mechanical peeling, chemical mechanical polishing (CMP), mechanical grinding, thermal baking, etc., such that the carrier board 201 may be peeled off.

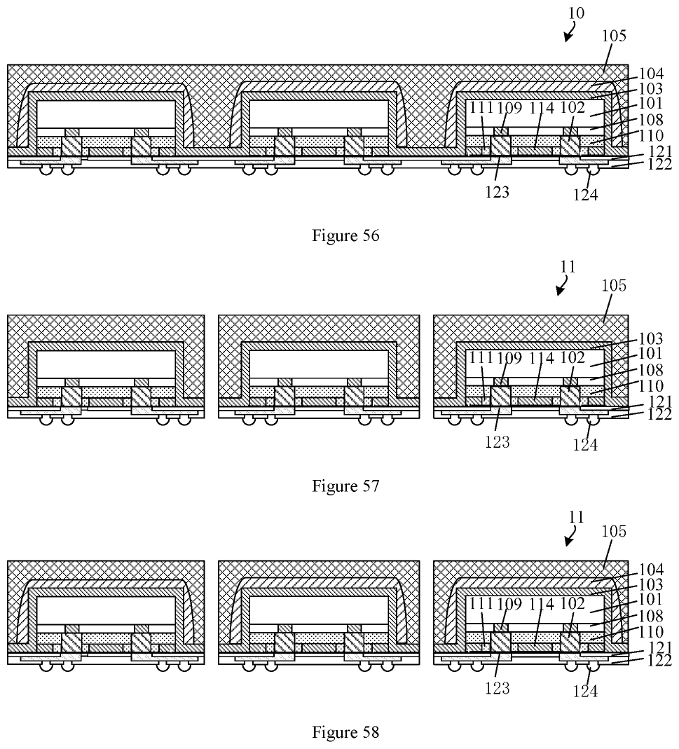

Referring to FIG. 55 (on the basis of FIG. 53) or FIG. 56 (on the basis of FIG. 54), an external contact structure connected to the pad 102 may be formed on the back side of the pre-encapsulation panel 10. In one embodiment, the external contact structure may include a rewiring layer 123 located on the back side of the pre-encapsulation panel 10 and connected to the pad 102, and an external contact element 124 located on the rewiring layer 123 and connected to the rewiring layer 123. The pad 102 on each semiconductor chip 101 may be connected to a corresponding external contact structure.

In one embodiment, the process of forming the rewiring layer 123 and the external contact element 124 may include following. An insulating layer (first insulating layer) 121 may be formed on the back side of the pre-encapsulation panel 10. The insulating layer (first insulating layer) 121 may have an opening that exposes the surface of the pad 102. The material of the insulating layer (first insulating layer) 121 may include silicon nitride, borosilicate glass, phosphorous silicate glass, or borophosphosilicate glass. The rewiring layer 123 may be formed in the opening and on partial surface of the insulating layer (first insulating layer) 121. An external contact element 124 may be formed on the surface of the rewiring layer outside the opening.

In one embodiment, the external contact element 124 may be a solder ball. In another embodiment, the external contact element 124 may include a metal pillar and a solder ball located on the metal pillar. The process of forming the external contact element 124 may include following. An insulating layer (second insulating layer) 122 may be formed on the insulating layer (first insulating layer) 121 and on the rewiring layer 123. The insulating layer (second insulating layer) 122 may have a second opening exposing partial surface of the rewiring layer 123 on the surface of the insulating layer (first insulating layer) 121. The external contact element 124 may be formed in the second opening.

In one embodiment, a conductive contact structure (not illustrated in the Figure) that electrically connects the first shielding layer 103 and a portion of the rewiring layer 123 may be formed on the insulating layer (first insulating layer) 121, such that the shielding layer may discharge or block external electrostatic interference through the portion of the rewiring layer 123.

Referring to FIG. 57 (on the basis of FIG. 55) or FIG. 58 (on the basis of FIG. 56), after forming the external contact structure, the pre-encapsulation panel 10 may be cut to form a plurality of discrete packaging structures 11.

Each packaging structure 11 may include the encapsulation layer 105. The encapsulation layer 105 may contain a semiconductor chip 101 therein. The semiconductor chip 101 may include the functional surface and the non-functional surface opposite to the functional surface. The plurality of pads 102 may be formed on the functional surface. The encapsulation layer 105 may expose the plurality of pads on the functional surface.

Each packaging structure may further include the bottom shielding layer 114 formed on the functional surface of the semiconductor chip 101. The bottom shielding layer 114 may cover the entire functional surface of the semiconductor chip 101, and the peripheral edge of the bottom shielding layer 114 may be flush with the surrounding sidewall of the semiconductor chip 101. The plurality of pads 102 may penetrate through the bottom shielding layer 114. The pad 102 may be isolated from the bottom shielding layer 114 by the isolation layer 111.

Each packaging structure 11 may further include the first shielding layer 103 located between the semiconductor chip 101 and the encapsulation layer 105 (referring to FIG. 57). The first shielding layer 103 may cover the non-functional surface and the sidewall surface of the semiconductor chip 101. The first shielding layer 103 may be connected to the peripheral edge of the bottom shielding layer 114.

Each packaging structure 11 may further include the external contact structure located on the functional surface of the semiconductor chip 101 and connected to the pad 101. The external contact structure may include the rewiring layer 123 located on the back side of the pre-encapsulation panel 10 and connected to the pad 102, and the external contact element 124 located on the rewiring layer 123 and connected to the rewiring layer 123.

In one embodiment, referring to FIG. 58, the second shielding layer 104 may be disposed between the first shielding layer 103 and the encapsulation layer 105. The second shielding layer 104 may cover the surface of the first shielding layer 103.

The present disclosure may achieve the mass production of the packaging structures 11 having the first shielding layer 103 and the bottom shielding layer 114, or having the first shielding layer 103, the second shielding layer 104 and the bottom shielding layer 114 through the aforementioned semiconductor integrated manufacturing process, and may improve the production efficiency.

### Exemplary Embodiment 6

The present disclosure also provides a packaging structure. Referring to FIG. 11 or FIG. 20, the packaging structure may include a pre-encapsulation panel 10. The pre-encapsulation panel may include an encapsulation layer 105. The encapsulation layer 105 may contain a plurality of semiconductor chips 101 therein. Each semiconductor chip 101 may include a functional surface and a non-functional surface opposite to the functional surface. A plurality of pads 102 may be formed on the functional surface. The encapsulation layer 105 may expose the plurality of pads on the functional surface.

The packaging structure may also include a first shielding layer 103 and a second shielding layer 104 disposed between the semiconductor chip 101 and the encapsulation layer 105. The first shielding layer 103 may cover the non-functional surface and the sidewall surface of the semiconductor chip 101, and the surface of the first shielding layer 103 may have an ellipsoidal shape. The second shielding layer 104 may be located between the first shielding layer 103 and the encapsulation layer 105, and may fully cover the surface of the first shielding layer 103 on the non-functional surface and the sidewall surface of the semiconductor chip 101.

Further, the packaging structure may include an external contact structure located on the back side of the pre-encapsulation panel and connected to the pad.

In one embodiment, the first shielding layer 103 may be directly formed on the non-functional surface and the sidewall surface of the semiconductor chip through a dispensing process or a screen-printing process. The second shielding layer 104 may be formed by a sputtering process, a selective electroplating process, a dispensing process, or a screen-printing process. The material of the first shielding layer 103 may be solder or conductive silver paste, and the material of the second shielding layer 104 may be copper, tungsten, aluminum, solder, or conductive silver paste.

In another embodiment, the packaging structure may further include an intermediate material layer disposed on the non-functional surface and the sidewall surface of the semiconductor chip 101. The intermediate material layer may have an ellipsoidal surface. The first shielding layer may be disposed on the surface of the intermediate material layer, and the first shielding layer may also have an ellipsoidal surface.

In one embodiment, the first shielding layer 103 may be a magnetic field shielding layer, and the second shielding layer 104 may be an electric field shielding layer. In another embodiment, the first shielding layer 103 may be an electric field shielding layer, and the second shielding layer 104 may be a magnetic field shielding layer. The material of the electric field shielding layer may include copper, tungsten, or aluminum. The material of the magnetic field shielding layer may include CoFeB alloy, CoFeTa alloy, NiFe alloy, Co, CoFe alloy, CoPt alloy, or an alloy of Ni, Co, and Fe.

In one embodiment, referring to FIG. 20, the packaging structure may further include a bottom shielding layer 114 formed on the functional surface of the semiconductor chip 101. The bottom shielding layer 114 may cover the entire functional surface of the semiconductor chip 101, and the peripheral edge of the bottom shielding layer 114 may be flush with the surrounding sidewall of the semiconductor chip 101. The plurality of pads 102 may penetrate through the bottom shielding layer 114. The pad 102 may be isolated from the bottom shielding layer 114 by an isolation layer 111. The first shielding layer 103 may be connected to the peripheral edge of the bottom shielding layer 114.

In one embodiment, the external contact structure may include a rewiring layer 123 located on the back side of the pre-encapsulation panel and connected to the pad 102, and an external contact element 124 located on the rewiring layer 123 and connected to the rewiring layer 123.

In one embodiment, the packaging structure may further include an insulating layer (first insulating layer) 121 formed on the back side of the pre-encapsulation panel. The insulating layer (first insulating layer) 121 may have an opening that exposes the surface of the pad 102. The rewiring layer 123 may be formed in the opening and on partial surface of the insulating layer (first insulating layer) 121. The external contact element 124 may be located on the surface of the rewiring layer 123 outside the opening.

In one embodiment, the packaging structure may further include an insulating layer (second insulating layer) 122 covering the insulating layer (first insulating layer) 121. A portion of the external contact element 124 may be located in the insulating layer (second insulating layer) 122.

In one embodiment, the packaging structure may further include a conductive contact structure (not illustrated in the Figure) that electrically connects the first shielding layer 103 and a portion of the rewiring layer 123 located in the insulating layer 121.

### Exemplary Embodiment 7

The present disclosure also provides a packaging structure. Referring to FIG. 31 or FIG. 40, the packaging structure may include a pre-encapsulation panel 10. The pre-encapsulation panel may include an encapsulation layer 105. The encapsulation layer 105 may contain a plurality of semiconductor chips 101 therein. Each semiconductor chip 101 may include a functional surface and a non-functional surface opposite to the functional surface. A plurality of pads 102 may be formed on the functional surface. The encapsulation layer 105 may expose the plurality of pads on the functional surface.

The packaging structure may also include a first shielding layer 103 and a second shielding layer 104 disposed between the semiconductor chip 101 and the encapsulation layer 105. The first shielding layer 103 may cover the non-functional surface and the sidewall surface of the semiconductor chip 101. The second shielding layer 104 may be located between the first shielding layer 103 and the encapsulation layer 105, and may fully cover the surface of the first shielding layer 103 on the non-functional surface and the sidewall surface of the semiconductor chip 101.

Further, the packaging structure may include an external contact structure located on the back side of the pre-encapsulation panel and connected to the pad.

In one embodiment, the first shielding layer 103 may be formed by a sputtering process. The second shielding layer 104 may be formed by a selective electroplating process, a dispensing process, or a screen-printing process. The material of the first shielding layer 103 may include copper, tungsten, or aluminum, and the material of the second shielding layer 104 may be copper, solder, or conductive silver paste.

In one embodiment, the first shielding layer 103 may be a magnetic field shielding layer, and the second shielding layer 104 may be an electric field shielding layer. In another embodiment, the first shielding layer 103 may be an electric field shielding layer, and the second shielding layer 104 may be a magnetic field shielding layer. The material of the electric field shielding layer may include copper, tungsten, or aluminum. The material of the magnetic field shielding layer may include CoFeB alloy, CoFeTa alloy, NiFe alloy, Co, CoFe alloy, CoPt alloy, or an alloy of Ni, Co, and Fe.

In one embodiment, referring to FIG. 40, the packaging structure may further include a bottom shielding layer 114 formed on the functional surface of the semiconductor chip 101. The bottom shielding layer 114 may cover the entire functional surface of the semiconductor chip 101, and the peripheral edge of the bottom shielding layer 114 may be flush with the surrounding sidewall of the semiconductor chip 101. The plurality of pads 102 may penetrate through the bottom shielding layer 114. The pad 102 may be isolated from the bottom shielding layer 114 by an isolation layer 111. The first shielding layer 103 may be connected to the peripheral edge of the bottom shielding layer 114.

In one embodiment, the external contact structure may include a rewiring layer 123 located on the back side of the pre-encapsulation panel and connected to the pad 102, and an external contact element 124 located on the rewiring layer 123 and connected to the rewiring layer 123.

In one embodiment, the packaging structure may further include an insulating layer (first insulating layer) 121 formed on the back side of the pre-encapsulation panel. The insulating layer (first insulating layer) 121 may have an opening that exposes the surface of the pad 102. The rewiring layer 123 may be formed in the opening and on partial surface of the insulating layer (first insulating layer) 121. The external contact element 124 may be located on the surface of the rewiring layer 123 outside the opening.

In one embodiment, the packaging structure may further include an insulating layer (second insulating layer) 122 covering the insulating layer (first insulating layer) 121. A portion of the external contact element 124 may be located in the insulating layer (second insulating layer) 122.

In one embodiment, the packaging structure may further include a conductive contact structure (not illustrated in the Figure) that electrically connects the first shielding layer 103 and a portion of the rewiring layer 123 located in the insulating layer 121.

### Exemplary Embodiment 8

The present disclosure also provides a packaging structure. Referring to FIG. 55, the packaging structure may include a pre-encapsulation panel 10. The pre-encapsulation panel may include an encapsulation layer 105. The encapsulation layer 105 may contain a plurality of semiconductor chips 101 therein. Each semiconductor chip 101 may include a functional surface and a non-functional surface opposite to the functional surface. A plurality of pads 102 may be formed on the functional surface. The encapsulation layer 105 may expose the plurality of pads on the functional surface.

The packaging structure may further include a bottom shielding layer 114 formed on the functional surface of the semiconductor chip 101. The bottom shielding layer 114 may cover the entire functional surface of the semiconductor chip 101, and the peripheral edge of the bottom shielding layer 114 may be flush with the surrounding sidewall of the semiconductor chip 101. The plurality of pads 102 may penetrate through the bottom shielding layer 114. The pad 102 may be isolated from the bottom shielding layer 114 by an isolation layer 111.

The packaging structure may further include the first shielding layer 103 located between the semiconductor chip 101 and the encapsulation layer 105. The first shielding layer 103 may cover the non-functional surface and the sidewall surface of the semiconductor chip 101. The first shielding layer 103 may be connected to the peripheral edge of the bottom shielding layer 114.

The packaging structure may further include an external contact structure located on the back side of the pre-encapsulation panel and connected to the pad.

In one embodiment, the first shielding layer 103 may be formed by a sputtering process, a selective electroplating process, a dispensing process, or a screen-printing process. The first shielding layer may also cover the surface of the carrier board between the semiconductor chips. The material of the first shielding layer 103 may include copper, tungsten, aluminum, solder, or conductive silver paste.

In one embodiment, referring to FIG. 56, a second shielding layer 104 may be formed between the first shielding layer 103 and the encapsulation layer 105. The second shielding layer 104 may cover the surface of the first shielding layer 103.

In one embodiment, the first shielding layer 103 may be a magnetic field shielding layer, and the second shielding layer 104 may be an electric field shielding layer. In another embodiment, the first shielding layer 103 may be an electric field shielding layer, and the second shielding layer 104 may be a magnetic field shielding layer. The material of the electric field shielding layer may include copper, tungsten, or aluminum. The material of the magnetic field shielding layer may include CoFeB alloy, CoFeTa alloy, NiFe alloy, Co, CoFe alloy, CoPt alloy, or an alloy of Ni, Co, and Fe.

In one embodiment, the external contact structure may include a rewiring layer 123 located on the back side of the pre-encapsulation panel and connected to the pad 102, and an external contact element 124 located on the rewiring layer 123 and connected to the rewiring layer 123.

In one embodiment, the packaging structure may further include an insulating layer (first insulating layer) 121 formed on the back side of the pre-encapsulation panel. The insulating layer (first insulating layer) 121 may have an opening that exposes the surface of the pad 102. The rewiring layer 123 may be formed in the opening and on partial surface of the insulating layer (first insulating layer) 121. The external contact element 124 may be located on the surface of the rewiring layer 123 outside the opening.

In one embodiment, the packaging structure may further include an insulating layer (second insulating layer) 122 covering the insulating layer (first insulating layer) 121. A portion of the external contact element 124 may be located in the insulating layer (second insulating layer) 122.

In one embodiment, the packaging structure may further include a conductive contact structure (not illustrated in the Figure) that electrically connects the first shielding layer 103 and a portion of the rewiring layer 123 located in the insulating layer 121.

In the disclosed embodiments of the present disclosure, the packaging structure may include the first shielding layer and the second shielding layer disposed between the semiconductor chip and the encapsulation layer. The first shielding layer may cover the non-functional surface and the sidewall surface of the semiconductor chip, and the surface of the first shielding layer may have an ellipsoidal shape. The second shielding layer may be located between the first shielding layer and the encapsulation layer, and may fully cover the surface of the first shielding layer on the non-functional surface and the sidewall surface of the semiconductor chip.

The first shielding layer having an ellipsoidal shape may uniformly and fully cover the non-functional surface and the sidewall surface of the semiconductor chip. Further, when forming the second shielding layer on the ellipsoidal surface of the first shielding layer, the second shielding layer may not have the issues of uneven thickness and poor edge coverage. Therefore, the overall shielding layer formed by both the first shielding layer and the second shielding layer may be intact, which may improve the shielding effect.

In addition, the first shielding layer may be a magnetic field shielding layer, and the formed second shielding layer may be an electric field shielding layer. Alternatively, the first shielding layer may be an electric field shielding layer, and the formed second shielding layer may be a magnetic field shielding layer. The formed first shielding layer and the second shielding layer having the above disclosed structure may shield the electric field and the magnetic field, respectively, thereby improving the shielding effect of the shielding layer. Further, the second shielding layer may cover the first shielding layer where the thickness is uneven and edge is not well covered. Therefore, the overall shielding layer formed by both the first shielding layer and the second shielding layer may be intact, which may improve the shielding effect.

Moreover, the intermediate material layer may be formed on the non-functional surface and sidewall surface of the semiconductor chip. The intermediate material layer may have an ellipsoidal surface. The first shielding layer may be formed on the surface of the intermediate material layer, and the first shielding layer may also have an ellipsoidal surface. By forming the intermediate material layer having an ellipsoidal surface, the first shielding layer made of different materials may be formed on the intermediate material layer through various processes, and the formed first shielding layer may also have an ellipsoidal surface. When forming the first shielding layer on the ellipsoidal surface of the intermediate material layer, the first shielding layer may not be affected by the sharp corner or steep sidewall, such that the formed first shielding layer may not have the issues of uneven thickness and poor edge coverage, thereby improving the integrity of the shielding layer.

Further, after forming the external contact structure, the pre-encapsulation panel may be cut to form a plurality of discrete packaging structures. Therefore, the mass production of the packaging structures having the first shielding layer and the second shielding layer may be achieved, thereby improving the production efficiency.

Further, the bottom shielding layer may be formed on the functional surface of the semiconductor chip. The bottom shielding layer may cover the entire functional surface of the semiconductor chip. The peripheral edge of the bottom shielding layer may be flush with the peripheral sidewall of the semiconductor chip. The plurality of pads may penetrate through the bottom shielding layer, and the pad may be isolated from the bottom shielding layer through the isolation layer. When forming the first shielding layer, the first shielding layer may be connected to the peripheral edge of the bottom shielding layer.

Further, the process of forming the bottom shielding layer may be integrated with the existing semiconductor chip manufacturing process. The bottom shielding layer and the pad may be simultaneously formed, which may simplify the manufacturing process, may reduce the process difficulty, and may improve the efficiency.

In the present disclosure, after forming the first shielding layer, the second shielding layer may also be formed on the first shielding layer, such that the second shielding layer may cover the first shielding layer where the thickness is uneven and edge is not well covered. Therefore, the overall shielding layer formed by both the first shielding layer and the second shielding layer may be intact, which may improve the shielding effect. Because the bottom shielding layer is also formed on the functional surface of the semiconductor chip, when forming the first shielding layer, the first shielding layer may be connected to the peripheral edge of the bottom shielding layer. Therefore, the semiconductor chip in the packaging structure may be fully or comprehensively covered by the bottom shielding layer and the first shielding layer. The electric field and magnetic field may not enter the packaging structure through the bottom of the packaging structure to bring electromagnetic interference to the semiconductor chip, thereby achieving the all-round electromagnetic shielding for the semiconductor chip, and further improving the electromagnetic shielding effect.

The description of the disclosed embodiments is provided to illustrate the present invention to those skilled in the art. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A packaging structure, comprising:
a pre-encapsulation panel, wherein the pre-encapsulation panel includes an encapsulation layer, the encapsulation layer contains a plurality of semiconductor chips, each semiconductor chip of the plurality of semiconductor chips includes a functional surface and a non-functional surface opposite to the functional surface, a plurality of pads are formed on the functional surface, and the encapsulation layer exposes the plurality of pads on the functional surface;
a first shielding layer and a second shielding layer disposed between a semiconductor chip of the plurality of semiconductor chips and the encapsulation layer, wherein the first shielding layer covers the non-functional surface and a sidewall surface of the semiconductor chip, the second shielding layer is disposed between the first shielding layer and the encapsulation layer and fully covers a surface of the first shielding layer on the non-functional surface and the sidewall surface of the semiconductor chip; and
an external contact structure disposed on a back side of the pre-encapsulation panel and connected to a pad of the plurality of pads.

2. The packaging structure according to claim 1, wherein:
the surface of the first shielding layer has an ellipsoidal shape.

3. The packaging structure according to claim 1, wherein:
one of the first shielding layer and the second shielding layer is an electric field shielding layer; and
another of the first shielding layer and the second shielding layer is a magnetic field shielding layer.

4. The packaging structure according to claim 3, wherein:
a material of the electric field shielding layer includes copper, tungsten, or aluminum; and
a material of the magnetic field shielding layer includes CoFeB alloy, CoFeTa alloy, NiFe alloy, Co, CoFe alloy, CoPt alloy, or an alloy of Ni, Co, and Fe.

5. The packaging structure according to claim 1, further including:
a bottom shielding layer formed on the functional surface of the semiconductor chip, wherein the bottom shielding layer covers the entire functional surface of the semiconductor chip, peripheral edge of the bottom shielding layer is flush with a surrounding sidewall of the semiconductor chip, the plurality of pads penetrate through the bottom shielding layer, the pad is isolated from the bottom shielding layer by an isolation layer, and the first shielding layer is connected to the peripheral edge of the bottom shielding layer.

6. The packaging structure according to claim 1, wherein:
the external contact structure includes a rewiring layer disposed on the back side of the pre-encapsulation panel and connected to the pad, and an external contact element disposed on the rewiring layer and connected to the rewiring layer.

7. The packaging structure according to claim 6, further including:
an insulating layer formed on the back side of the pre-encapsulation panel, wherein the insulating layer has an opening that exposes a surface of the pad, the rewiring layer is formed in the opening and on a partial surface of the insulating layer, and the external contact element is disposed on a surface of the rewiring layer outside the opening.

8. The packaging structure according to claim 7, further including:
a conductive contact structure in the insulating layer for electrically connecting the first shielding layer and a portion of the rewiring layer.

9. A packaging structure, comprising:
a pre-encapsulation panel, wherein the pre-encapsulation panel includes an encapsulation layer, the encapsulation layer contains a plurality of semiconductor chips, each semiconductor chip of the plurality of semiconductor chips includes a functional surface and a non-functional surface opposite to the functional surface, a plurality of pads are formed on the functional surface, and the encapsulation layer exposes the plurality of pads on the functional surface;
a bottom shielding layer formed on the functional surface of a semiconductor chip of the plurality of semiconductor chips, wherein the bottom shielding layer covers the entire functional surface of the semiconductor chip, peripheral edge of the bottom shielding layer is flush with a surrounding sidewall of the semiconductor chip, the plurality of pads penetrate through the bottom shielding layer, and a pad of the plurality of pads is isolated from the bottom shielding layer by an isolation layer;
a first shielding layer disposed between the semiconductor chip and the encapsulation layer, wherein the first shielding layer covers the non-functional surface and a sidewall surface of the semiconductor chip, and the first shielding layer is connected to the peripheral edge of the bottom shielding layer; and
an external contact structure disposed on a back side of the pre-encapsulation panel and connected to the pad.

10. The packaging structure according to claim 9, further including:
a second shielding layer disposed between the first shielding layer and the encapsulation layer, wherein the second shielding layer covers a surface of the first shielding layer.

11. The packaging structure according to claim 9, further including:
a metal bump formed on the pad.

12. A method for forming a packaging structure, comprising:
providing a plurality of semiconductor chips, wherein each semiconductor chip of the plurality of semiconductor chips includes a functional surface and a non-functional surface opposite to the functional surface, and a plurality of pads are formed on the functional surface;
providing a carrier board;
adhering the functional surface of the each semiconductor chip to the carrier board;
forming a first shielding layer to cover the non-functional surface and a sidewall surface of a semiconductor chip of the plurality of semiconductor chips;
forming one or more of a second shielding layer and a bottom shielding layer, wherein the second shielding layer fully covers a surface of the first shielding layer, the bottom shielding layer covers the entire functional surface of the semiconductor chip, peripheral edge of the bottom shielding layer is flush with a surrounding sidewall of the semiconductor chip, the plurality of pads penetrate through the bottom shielding layer, and a pad of the plurality of pads is isolated from the bottom shielding layer by an isolation layer;
forming an encapsulation layer over the first shielding layer and over the carrier board between semiconductor chips of the plurality of semiconductor chips;
forming a pre-encapsulation panel by peeling off the carrier board; and
forming an external contact structure on the back side of the pre-encapsulation panel and connected to the pad.

13. The method according to claim 12, wherein:
the first shielding layer is directly formed on the non-functional surface and the sidewall surface of the each semiconductor chip by a dispensing process or a screen-printing process; and
the second shielding layer is formed by a sputtering process, a selective electroplating process, a dispensing process, or a screen-printing process.

14. The method according to claim 13, wherein:
a material of the first shielding layer includes solder, or conductive silver paste; and
a material of the second shielding layer includes copper, tungsten, aluminum, solder, or conductive silver paste.

15. The method according to claim 12, wherein:
the first shielding layer is formed by a sputtering process, a selective electroplating process, a dispensing process, or a screen-printing process,
the first shielding layer at least covers a partial surface of the carrier board between the semiconductor chips, and
a material of the first shielding layer includes copper, tungsten, aluminum, solder, or conductive silver paste.

16. The method according to claim 12, wherein:
the plurality of pads and the bottom shielding layer are formed by a same process.

17. The method according to claim 12, wherein:
the external contact structure includes a rewiring layer disposed on the back side of the pre-encapsulation panel and connected to the pad, and an external contact element disposed on the rewiring layer and connected to the rewiring layer.

18. The method according to claim 17, after peeling off the carrier board, further including:
forming an insulating layer on the back side of the pre-encapsulation panel, wherein the insulating layer has an opening that exposes a surface of the pad, the rewiring layer is formed in the opening and on a partial surface of the insulating layer, the external contact element is disposed on a surface of the rewiring layer outside the opening.

19. The method according to claim 18, further including:
forming a conductive contact structure in the insulating layer for electrically connecting the first shielding layer and a portion of the rewiring layer.

20. The method according to claim 12, further including:
cutting the pre-encapsulation panel to form a plurality of discrete packaging structures.
